(19) United States
(12) Patent Application Publication
(10) Pub. No.: US 2026/0371857 A1
(43) Pub. Date: Nov. 19, 2026

(54) DISPLAY DEVICE AND ELECTRONIC DEVICE INCLUDING THE SAME

(71) Applicant: Samsung Display Co., Ltd., Yongin-si (KR)

(72) Inventors: Jun Ho SIM, Yongin-si (KR); Youn Joo RYU, Yongin-si (KR); Sang Hyun YUN, Yongin-si (KR)

(21) Appl. No.: 19/541,245

(22) Filed: Feb. 16, 2026

(30) Foreign Application Priority Data
May 19, 2025 (KR) 10-2025-0064519

(51) Int. Cl. H10K 59/122; H10H 29/01; H10H 29/37; H10H 29/80; H10H 29/85; H10H 29/854; H10K 59/12; H10K 59/35; H10K 59/38; H10K 59/65; H10K 59/80; H10K 102/00

(52) U.S. Cl. CPC H10K 59/122; H10H 29/012; H10H 29/37; H10H 29/8321; H10H 29/8517; H10H 29/854; H10K 59/1201; H10K 59/353; H10K 59/38; H10K 59/65; H10K 59/80521; H10K 59/873; H10K 2102/351

(57) ABSTRACT

A display device and electronic device including the same are provided. The display device includes a display area having a first display area and a second display area adjacent the first display area, a substrate, a thin-film transistor layer on the substrate and including at least one conductive pattern, an emission material layer on the thin-film transistor layer and including a pixel-defining layer, and an optical device in the second display area. The pixel-defining layer includes a partition wall defining a plurality of openings, and the plurality of openings define a plurality of emission areas. The partition wall includes a first portion and a second portion, and a thickness of the first portion is greater than a thickness of the second portion.

### CROSS-REFERENCE TO RELATED APPLICATION

The present application claims priority to and the benefit of Korean Patent Application No. 10-2025-0064519, filed on May 19, 2025, in the Korean Intellectual Property Office, the entire disclosure of which is incorporated herein by reference.

### BACKGROUND

### 1. Field

Embodiments of the present disclosure relate to a display device and an electronic device including the same.

### 2. Description of the Related Art

As our information-oriented society evolves, the demand or desire for display devices is ever increasing. Display devices may include liquid-crystal display devices, field emission display devices, light-emitting display devices, and/or the like. Light-emitting display devices may include organic light-emitting display devices including organic light-emitting diodes as light-emitting elements, inorganic light-emitting display devices including inorganic light-emitting diodes as light-emitting elements, and/or the like.

A display device may include a variety of optical devices, such as an image sensor for capturing an image on the front side, a proximity sensor for detecting whether a user is located close to the front side of the display device, an illuminance sensor for detecting the illuminance of the front side of the display device, and an iris sensor for recognizing a user's iris.

The above information disclosed in this Background section is intended to enhance understanding of the background of the disclosure and may contain information that does not constitute prior art.

### SUMMARY

Aspects of one or more embodiments of the present disclosure are directed toward a display device including a display panel with improved transmittance, and an electronic device including the same.

Aspects of one or more embodiments of the present disclosure are directed toward a display device including an optical device with an increased amount of incident light, and an electronic device including the same.

Additional aspects will be set forth in part in the description which follows and, in part, will be apparent from the description, or may be learned by practice of the presented embodiments of the disclosure.

According to one or more embodiments of the present disclosure, a display device includes a display area having a first display area and a second display area adjacent the first display area, a substrate, a thin-film transistor layer on the substrate and including at least one conductive pattern, an emission material layer on the thin-film transistor layer and including a pixel-defining layer, and an optical device in the second display area. The pixel-defining layer includes a partition wall defining a plurality of openings, and the plurality of openings define a plurality of emission areas. The partition wall includes a first portion and a second portion, and a thickness of the first portion is greater than a thickness of the second portion. In one or more embodiments, the second portion may located in the second display area.

In one or more embodiments, the pixel-defining layer may include the first portion but not the second portion in the first display area.

In one or more embodiments, the partition wall of the pixel-defining layer may define a groove in the second display area, and the second portion overlaps the groove.

In one or more embodiments, the first portion may be around (e.g., may surround) the plurality of emission areas when viewed from the top (e.g., in a plan view), and the second portion may be around (e.g., may surround) the first portion when viewed from the top (e.g., in a plan view).

In one or more embodiments, the second portion may be located in a remaining area of the second display area excluding the plurality of emission areas and the first portion.

In one or more embodiments, the thickness of the first portion may be in a range from 1 µm to 2 µm, and the thickness of the second portion may be equal to or less than 0.5 µm.

In one or more embodiments, the pixel-defining layer may further include a third portion including a part of the partition wall and a spacer on the part of the partition wall, and wherein a thickness of the third portion may be greater than each of the thicknesses of the first portion and the second portion.

In one or more embodiments, the thickness of the third portion may be in a range from 2.5 μm to 3.5 μm.

In one or more embodiments, the plurality of emission areas may include a plurality of light-emitting elements, wherein each of the plurality of light-emitting elements includes a first electrode, an emissive layer and a second electrode, wherein the first electrode may be located under the pixel-defining layer, wherein the emissive layer may be located in a respective one of the plurality of openings, wherein the second electrode may be located on the pixel-defining layer, and wherein the second electrode may be formed conformally along (e.g., may conform to the shape of) an upper surface and side surfaces of the pixel-defining layer.

In one or more embodiments, the display device may further include, an encapsulation layer arranged on the emission material layer, wherein the encapsulation layer includes a first encapsulation layer including an inorganic film, a second encapsulation layer located on the first encapsulation layer and including an organic film, and a third encapsulation layer located on the second encapsulation layer and including an inorganic film, and wherein the first encapsulation layer is formed conformally along (e.g., may conform to the shape of) an upper surface and side surfaces of the second electrode.

In one or more embodiments, the second encapsulation layer may include a flat surface over the first encapsulation layer having different heights (e.g., an upper surface of the first encapsulation layer may be uneven, e.g., may have different heights, and second encapsulation layer may cover the first encapsulation layer to provide a flat surface).

In one or more embodiments, the first portion may include a plurality of first portions, the second display area may further include a transparent window around (e.g., surrounding) the plurality of emission areas and the plurality of first portions, the pixel-defining layer may not be arranged in the transparent window, the second portion may include a bridge for connecting adjacent ones of the plurality of first portions.

In one or more embodiments, each of the plurality of emission areas may include a plurality of light-emitting elements, wherein each of the plurality of light-emitting elements include a first electrode, an emissive layer and a second electrode, wherein the first electrode may be located under the pixel-defining layer, wherein the emissive layer may be located in the plurality of openings, wherein the second electrode may be located on the pixel-defining layer, and wherein the second electrode may be in direct contact with the thin-film transistor layer at the transparent window.

In one or more embodiments, the second display area may further include a transparent window around (e.g., surrounding) the plurality of emission areas and the plurality of first portions, wherein the pixel-defining layer may not be arranged in the transparent window, and wherein the second portion of the pixel-defining layer may overlap the conductive pattern.

In one or more embodiments, the second display area may include transparent windows in a closed region arranged between the plurality of emission areas.

In one or more embodiments, the pixel-defining layer may include a light-absorbing material.

In one or more embodiments, the display device may further include, a color filter layer arranged on the emission material layer, wherein the color filter layer may include a plurality of color filters overlapping the plurality of emission areas and the plurality of openings.

In one or more embodiments, the pixel-defining layer is formed using a halftone mask, wherein the halftone mask includes a first transmissive portion in line with (e.g., configured to overlap) the first portion, a second transmissive portion in line with (e.g., configured to overlap) the second portion, and a third transmissive portion in line with (e.g., configured to overlap) the plurality of openings, and wherein the first to third transmissive portions may have different transmittances.

According to one or more embodiments of the present disclosure, an electronic device includes a display device for displaying an image, the display device having a first display area and a second display area adjacent the first display area, a processor for providing an image driving signal to the display device, and a power module for supplying power to the display device and the processor, wherein the display device includes a substrate, a thin-film transistor layer arranged on the substrate and including at least one conductive pattern, an emission material layer arranged on the thin-film transistor layer and including a pixel-defining layer, the pixel-defining layer comprising a partition wall defining a plurality of openings, and the plurality of openings defining a plurality of emission areas, and an optical device located in the second display area, The pixel-defining layer includes a first portion and a second portion and the thickness of the first portion is greater than the thickness of the second portion.

According to one or more embodiments of the present disclosure, the transmittance of a display panel of a display device may be improved.

According to one or more embodiments of the present disclosure, the amount of light incident on an optical device of a display device may be increased.

For example, one or more embodiments of the present disclosure provide a display device architecture that balances optical transmittance and structural integrity in regions overlapping an optical component. By selectively varying the thickness of portions of a pixel-defining layer—such as providing a first portion of greater thickness for partitioning emission areas, a second portion of reduced thickness for improved light transmission, and optionally a third portion or transparent window for further enhancing transmittance—the display device may increase the amount of light incident on an optical device without sacrificing durability or pixel isolation. These structural variations also enable integration of encapsulation layers and color filters while maintaining a flat upper surface, thereby improving reliability, reducing reflection of external light, and supporting high-quality image display. Accordingly, the disclosed configurations allow electronic devices to incorporate advanced optical sensing or imaging functions within the display area while preserving display performance and manufacturing efficiency.

It should be noted that aspects of the present disclosure are not limited to those described above and other aspects of the present disclosure will be apparent to those skilled in the art from the following descriptions.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a perspective view of an electronic device according to one or more embodiments of the present disclosure.

FIG. 2 is a perspective view showing a display device included in an electronic device according to one or more embodiments of the present disclosure.

FIG. 3 is a cross-sectional view of the display device of FIG. 2 along a second direction when a sub-area of the display device is bent, according to one or more embodiments of the present disclosure.

FIG. 4 is a plan view showing a display device according to one or more embodiments of the present disclosure.

FIG. 5 is a plan view showing a part of a first display area of a display device according to one or more embodiments of the present disclosure.

FIG. 6 is a cross-sectional view taken along the line X1 – X1' in FIG. 5, according to one or more embodiments of the present disclosure.

FIG. 7 is a cross-sectional view showing a part of a first display area of a display device according to one or more embodiments of the present disclosure.

FIG. 8 is a plan view showing a part of the second display area of the display device according to one or more embodiments of the present disclosure.

FIG. 9 is a cross-sectional view showing a part of the second display area and an optical device of the display device according to one or more embodiments of the present disclosure.

FIG. 10 is a graph showing the transmittance of a pixel-defining layer versus wavelength in the first display area of the display device according to one or more embodiments of the present disclosure.

FIG. 11 is a graph showing the optical density of the pixel-defining layer versus thickness of the display device according to one or more embodiments of the present disclosure.

FIG. 12 is a graph showing the transmittance of the pixel-defining layer versus wavelength of the display device for different thicknesses according to one or more embodiments of the present disclosure.

FIG. 13 is a plan view showing a part of a second display area of a display device according to one or more embodiments of the present disclosure.

FIG. 14 is a cross-sectional view showing a part of the second display area and an optical device of the display device of FIG. 13, according to one or more embodiments of the present disclosure.

FIG. 15 is a plan view showing a part of a second display area of a display device according to one or more embodiments of the present disclosure.

FIG. 16 is a plan view showing a part of a second display area of a display device according to one or more embodiments of the present disclosure.

FIG. 17 is a cross-sectional view showing a part of the second display area and an optical device of the display device of FIG. 16, according to one or more embodiments of the present disclosure.

FIGS. 18 − 20 are cross-sectional views showing processing steps of forming a pixel-defining layer in a display device, according to one or more embodiments of the present disclosure.

FIG. 21 is a block diagram of an electronic device according to one or more embodiments of the present disclosure.

FIG. 22 shows schematic perspective views of electronic devices according to a variety of embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that when an element, such as an area, layer, film, region or portion, is referred to as being “on” or “connected to” another element, it can be directly on or connected to the other element, or one or more intervening elements may be present. In contrast, when an element or layer is referred to as being “directly on,” “directly connected to”, or “immediately adjacent to” another element or layer, there are no intervening elements or layers present. In addition, it will also be understood that when an element is referred to as being “between” two elements, it can be the only element between the two elements, or one or more intervening elements may also be present. “”

Unless otherwise noted, like reference numerals denote like elements throughout the attached drawings and the written description, and thus, duplicative descriptions thereof may not be provided. In the drawings, the relative sizes (e.g., including lengths, widths and thicknesses) of elements, layers, and regions may be exaggerated for clarity.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “on,” “below,” “lower,” “under,” “above,” “upper,” and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

As used herein, the singular forms “a,” “an” and “the” are intended to include the plural forms as well, unless the context clearly indicates otherwise. It will be further understood that the terms “comprises,” “comprising,” “includes,” “including,” “have,” “having,” “contain,” and “containing,” when used in this specification, specify the presence of the stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having,” “contain/containing” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, the term “and/or” includes any and all combinations of one or more of the associated listed items. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As used herein, the terms “use,” “using,” and “used” may be considered synonymous with the terms “utilize,” “utilizing,” and “utilized,” respectively.

In the context of the present disclosure and unless otherwise defined, a plan view is an orthographic projection of a three-dimensional object from the position of a horizontal plane through the object. That is, it is a top-down view, showing the layout and spatial relationships of various elements within the object or structure. A plan view based on the direction DR3 refers to a top-down view of the display panel, as if looking directly down onto the surface from above. In this context, DR3 is the direction perpendicular or normal to the plane defined by the first direction DR1 and the second direction DR2. This refers to that in a plan view, the arrangement of sub-pixels, pads, and other components as they are laid out on the substrate can be seen, without any perspective distortion.

Hereinafter, embodiments of the present disclosure will be described in more detail with reference to the accompanying drawings.

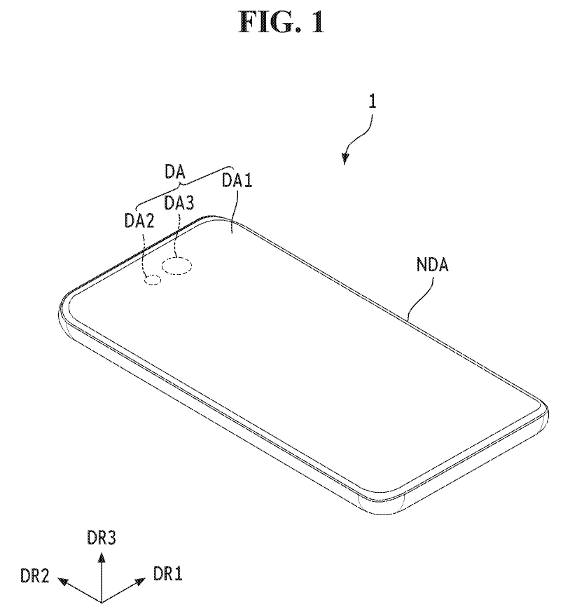

FIG. 1 is a perspective view of an electronic device according to one or more embodiments of the present disclosure.

Referring to FIG. 1, an electronic device 1 displays moving images or still images. The electronic device 1 may refer to any electronic device that provides a display screen. For example, the electronic device 1 may include a television set, a laptop computer, a monitor, an electronic billboard, the Internet of Things devices, a mobile phone, a smart phone, a tablet personal computer (PC), an electronic watch, a smart watch, a watch phone, a head-mounted display device, a mobile communications terminal, an electronic notebook, an electronic book, a portable multimedia player (PMP), a navigation device, a game console and a digital camera, a camcorder, and/or the like.

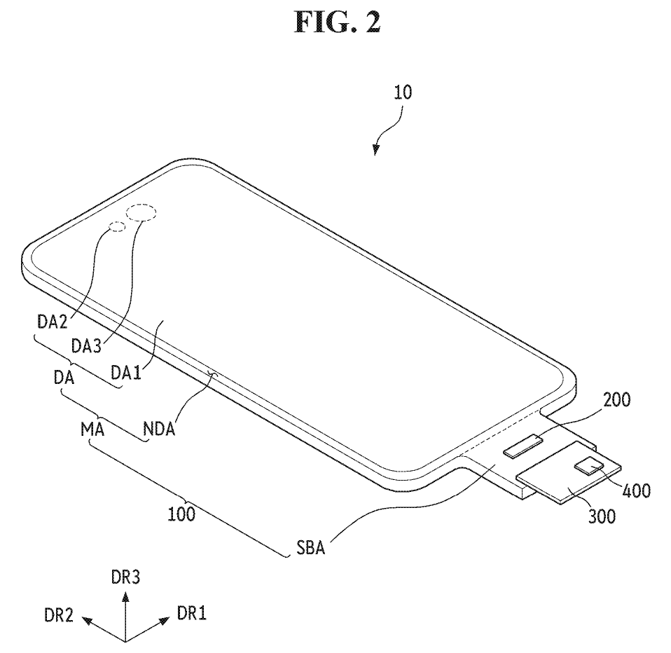

The electronic device 1 may include a display device 10 (see, e.g., FIG. 2) for providing a display screen. Examples of the display device may include an inorganic light-emitting diode display device, an organic light-emitting display device, a quantum-dot light-emitting display device, a plasma display device, a field emission display device, and/or the like. In the following description, an organic light-emitting diode display device is employed as an example of the display device, but the present disclosure is not limited thereto. Any other display device may be employed as long as the technical scope and/or spirit of the present disclosure can be equally applied.

The shape of the electronic device 1 may be modified in a variety of ways. For example, the electronic device 1 may have shapes such as a rectangle with longer lateral sides, a rectangle with longer vertical sides, a square, a quadrangle with rounded corners (vertices), other polygons, a circle, and/or the like. The shape of a display area DA of the electronic device 1 may also be similar to the overall shape of the electronic device 1. In the example shown in FIG. 1, the electronic device 1 has a rectangular shape with the longer sides in a second direction DR2.

In the drawings, the first direction DR1 and the second direction DR2 intersect each other as the horizontal directions. For example, the first direction DR1 and the second direction DR2 may be normal (e.g., perpendicular) to each other. In addition, a third direction DR3 may intersect the first direction DR1 and the second direction DR2, and may be a vertical direction, for example. Herein, the side indicated by the arrow of each of the first to third directions DR1, DR2 and DR3 may be referred to as a first side, while the opposite side may be referred to as a second side unless specifically state otherwise. As used herein, the terms “on,” “upper side,” “above,” “top” and “upper surface” refer to the side indicated by the arrow of the third direction DR3 as shown in the drawings. The terms “under,” “lower side,” “below,” “bottom” and “lower surface” refer to the opposite side indicated by the arrow of the third direction DR3 as shown in the drawings.

The electronic device 1 may include the display area DA and a non-display area NDA. In the display area DA, images can be displayed. In the non-display area NDA, images are not displayed. The display area DA may be referred to as an active area, while the non-display area NDA may also be referred to as an inactive area. The display area DA may generally occupy the center of the electronic device 1.

The display area DA may include a first display area DA1, a second display area DA2 and a third display area DA3. In the second display area DA2 and the third display area DA3, components for adding a variety of features to the electronic device 1 may be arranged. For example, the second display area DA2 and the third display area DA3 may be referred to as component areas.

Although the second display area DA2 and the third display area DA3 are separated in the drawings, the present disclosure is not limited thereto. The display device 10 may include only one of the second display area DA2 or the third display area DA3, or may include both. Both the second display area DA2 and the third display area DA3 may be component areas, and the types (kinds) of optical devices 500 arranged in each of the second display area DA2 and the third display area DA3 may be modified in one or more suitable ways. In the following description, the second display area DA2 will be described an example. It should be noted that the same technical features described with respect to the second display area DA2 can be applied to the third display area DA3.

FIG. 2 is a perspective view showing a display device included in an electronic device according to one or more embodiments of the present disclosure.

Referring to FIG. 2, the electronic device 1 according to one or more embodiments may include the display device 10. The display device 10 may provide a display screen of the electronic device 1 where images are displayed. The display device 10 may have a shape similar to that of the electronic device 1 when viewed from the top (e.g., in a plan view). For example, the display device 10 may have a shape similar to a rectangle having shorter sides in the first direction DR1 and longer sides in the second direction DR2. The corners where the shorter sides in the first direction DR1 meet the longer sides in the second direction DR2 may be rounded with a set or predetermined curvature. It should be understood, however, that the present disclosure is not limited thereto. The corners may be formed at a right angle. The shape of the display device 10 when viewed from the top (e.g., in a plan view) is not limited to a quadrangular shape, but may be formed in a shape similar to other polygonal shapes, a circular shape, or an elliptical shape.

The display device 10 may include a display panel 100, a display driver 200, a circuit board 300, and a touch driver 400.

The display panel 100 may include a main area MA and a subsidiary area SBA.

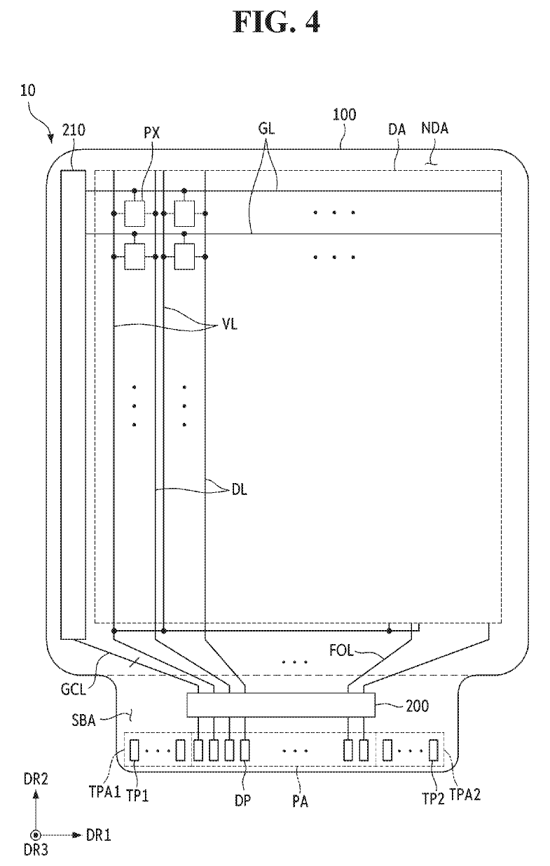

The main area MA may include a display area DA including pixels PX (see, e.g., FIG. 4) for displaying images, and a non-display area NDA located around the display area DA. The display area DA is located in the center of the main area MA, and the non-display area NDA may be around (e.g., surround) the display area DA. The display area DA may include the first display area DA1, the second display area DA2 and the third display area DA3. The display area DA may output light from a plurality of emission areas or a plurality of open areas. For example, the display panel 100 may include a pixel circuit including switching elements, a pixel-defining layer that defines the emission areas or the open areas, and self-light-emitting elements.

For example, the self-light-emitting element may include, but is not limited to, at least one of: an organic light-emitting diode including an organic emissive layer, a quantum-dot light-emitting diode (quantum LED) including a quantum-dot emissive layer, an inorganic light-emitting diode (inorganic LED) including an inorganic semiconductor, and a micro light-emitting diode (micro LED).

The non-display area NDA may be located on the outer side of the display area DA. The non-display area NDA may be defined as the edge area of the main area MA of the display panel 100. The non-display area NDA may include a gate driver that applies gate signals to gate lines, and fan-out lines that connect the display driver 200 with the display area DA.

The subsidiary area SBA may extend from one side of the main area MA. The subsidiary area SBA may include a flexible material that can be bent, folded, or rolled. For example, if (e.g., when) the subsidiary area SBA is bent, the subsidiary area SBA may overlap the main area MA in the thickness direction (third direction DR3). The subsidiary area SBA may include pads connected to the display driver 200 and the circuit board 300. According to one or more embodiments, the subsidiary area SBA may be eliminated, and the display driver 200 and the pads may be arranged in the non-display area NDA.

The display driver 200 may output signals and voltages for driving the display panel 100. The display driver 200 may supply data voltages to data lines. The display driver 200 may apply a supply voltage to a voltage line and may supply gate control signals to the gate driver. The display driver 200 may be implemented as an integrated circuit (IC) and may be attached on the display panel 100 by a chip-on-glass (COG) technique, a chip-on-plastic (COP) technique, or ultrasonic bonding. For example, the display driver 200 may be located in the subsidiary area SBA and may overlap with the main area MA in the thickness direction if (e.g., when) the subsidiary area SBA is bent. For another example, the display driver 200 may be mounted on the circuit board 300.

The circuit board 300 may be attached on the pad area of the display panel 100 using an anisotropic conductive film (ACF). Lead lines of the circuit board 300 may be electrically connected to the pads of the display panel 300. The circuit board 300 may be a flexible printed circuit board (FPCB), a printed circuit board (PCB), or a flexible film such as a chip-on-film (COF).

The touch driver 400 may be mounted on the circuit board 300. The touch driver 400 may be connected to a touch sensing unit of the display panel 100. The touch driver 400 may supply a touch driving signal to a plurality of touch electrodes of the touch sensing unit and may sense a change in the capacitance between the plurality of touch electrodes. For example, the touch driving signals may be pulse signals having a set or predetermined frequency. The touch driver 400 may determine whether there is an input and may find the coordinates of the input based on the amount of the change in the capacitance between the touch electrodes. The touch driver 400 may be implemented as an integrated circuit (IC).

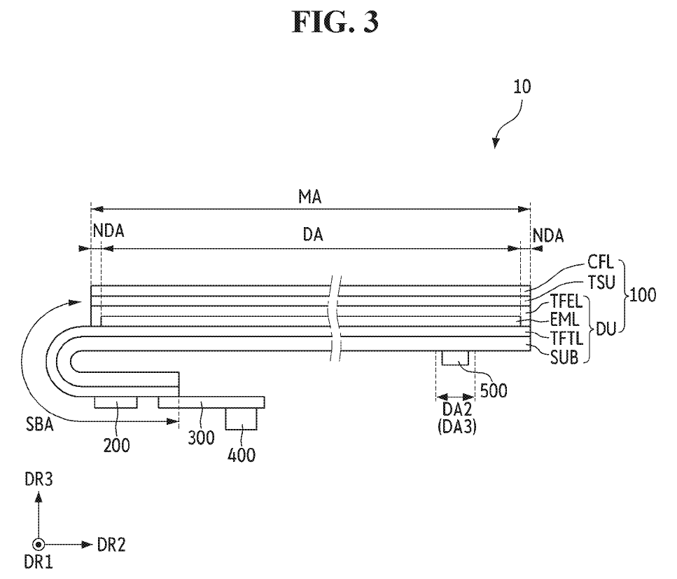

FIG. 3 is a cross-sectional view of the display device of FIG. 2 along the second direction DR2, according to one or more embodiments of the present disclosure. FIG. 3 shows the display device 10 of FIG. 2 if (e.g., when) the sub-area SBA of the display panel 100 is bent.

Referring to FIG. 3, the display panel 100 may include a display layer DU, a touch sensing layer TSU, and a color filter layer CFL. The display layer DU may include a substrate SUB, a thin-film transistor layer TFTL, an emission material layer EML and an encapsulation layer TFEL.

The substrate SUB may be a base substrate or a base member. The substrate SUB may be a flexible substrate that can be bent, folded, or rolled. For example, the substrate SUB may include, but is not limited to, a polymer resin such as polyimide PI. According to one or more embodiments, the substrate SUB may include a glass material or a metal material.

The thin-film transistor layer TFTL may be located on the substrate SUB. The thin-film transistor layer TFTL may include a plurality of thin-film transistors forming pixel circuits of pixels. The thin-film transistor layer TFTL may include gate lines, data lines, voltage lines, gate control lines, fan-out lines for connecting the display driver 200 with the data lines, lead lines for connecting the display driver 200 with the pads, and/or the like. Each of the thin-film transistors may include a semiconductor region, a source electrode, a drain electrode, and a gate electrode. For example, if (e.g., when) a gate driver is formed on one side of the non-display area NDA of the display panel 100, the gate driver may include thin-film transistors.

The thin-film transistor layer TFTL may be located in the display area DA, the non-display area NDA and the subsidiary area SBA. The thin-film transistors in each of the pixels, the gate lines, the data lines and the voltage lines in the thin-film transistor layer TFTL may be located in the display area DA. The gate control lines and the fan-out lines in the thin-film transistor layer TFTL may be arranged in the non-display area NDA. The lead lines of the thin-film transistor layer TFTL may be arranged in the subsidiary area SBA.

The emission material layer EML may be located on the thin-film transistor layer TFTL. The emission material layer EML may include a plurality of light-emitting elements each including a first electrode, a second electrode and an emissive layer to emit light, and a pixel-defining layer for defining the pixels. The plurality of light-emitting elements in the emission material layer EML may be arranged in the display area DA.

According to one or more embodiments of the present disclosure, the emissive layer may be an organic emissive layer containing an organic material. The emissive layer may include a hole transporting layer, an organic light-emitting layer and an electron transporting layer. When the first electrode receives a voltage and the second electrode receives a cathode voltage through the thin-film transistors on the thin-film transistor layer TFTL, the holes and electrons may move to the organic light-emitting layer through the hole transporting layer and the electron transporting layer, respectively, such that they combine in the organic light-emitting layer to emit light.

According to one or more embodiments, the light-emitting elements may include quantum-dot light-emitting diodes each including a quantum-dot emissive layer, inorganic light-emitting diodes each including an inorganic semiconductor, or micro light-emitting diodes.

An encapsulation layer TFEL may cover the upper and side surfaces of the emission material layer EML, and can protect the emission material layer EML. The encapsulation layer TFEL may include at least one inorganic film and at least one organic film for encapsulating the emission material layer EML.

The touch sensing layer TSU may be located on the encapsulation layer TFEL. The touch sensing layer TSU may include a plurality of touch electrodes for sensing a user's touch by capacitive sensing, and touch lines connecting the plurality of touch electrodes with the touch driver 400. For example, the touch sensing layer TSU may sense a user's touch by mutual capacitance sensing or self-capacitance sensing.

For another example, the touch sensing layer TSU may be located on a separate substrate located on the display layer DU. In such embodiments, the substrate supporting the touch sensing layer TSU may be a base member encapsulating the display layer DU.

The plurality of touch electrodes of the touch sensing layer TSU may be arranged in a touch sensor area overlapping the display area DA. The touch lines of the touch sensing layer TSU may be arranged in a touch peripheral area overlapping the non-display area NDA.

The color filter layer CFL may be placed on the touch sensing layer TSU. The color filter layer CFL may include a plurality of color filters associated with the plurality of emission areas, respectively. Each of the color filters may selectively transmit light of a particular wavelength and block, reduce, or absorb light of other wavelengths. The color filter layer CFL may be to absorb some of light introduced from outside of the display device 10 to reduce the reflection of external light. Accordingly, the color filter layer CFL can prevent or reduce distortion of colors due to the reflection of external light.

Because the color filter layer CFL is located directly on the touch sensing layer TSU, the display device 10 may require no separate substrate for the color filter layer CFL. Therefore, the thickness of the display device 10 can be reduced or relatively small.

In one or more embodiments, the display device 10 may further include an optical device 500. The optical device 500 may be located in the second display area DA2 or the third display area DA3. The optical device 500 may output or receive light in infrared, ultraviolet, and visible ranges. For example, the optical device 500 may be an optical sensor that senses light incident on the display device 10, such as a proximity sensor, an illuminance sensor, a camera sensor and/or an image sensor.

FIG. 4 is a plan view showing a display device according to one or more embodiments of the present disclosure.

Referring to FIG. 4, a display panel 100 may include a display area DA and a non-display area NDA.

The display area DA may be located at the center of display device 100. A plurality of pixels PX, a plurality of gate lines GL, a plurality of data lines DL, and a plurality of voltage lines may be located in the display area DA. Each of the plurality of pixels PX may be defined as the minimum unit that outputs light.

The plurality of gate lines GL may supply the gate signals received from the gate driver 210 to the plurality of pixels PX. The plurality of gate lines GL may extend in the first direction DR1 and may be spaced and/or apart (e.g., spaced apart or separated) from one another in the second direction DR2 intersecting the first direction DR1.

The plurality of data lines DL may supply the data voltages received from the display driver 200 to the plurality of pixels PX. The plurality of data lines DL may extend in the second direction DR2 and may be spaced and/or apart (e.g., spaced apart or separated) from one another in the first direction DR1.

The plurality of voltage lines VL may apply the supply voltage received from the display driver 200 to the plurality of pixels PX. The supply voltage may be at least one of a driving voltage, an initialization voltage, a reference voltage and/or a low-level voltage. The plurality of voltage lines VL may extend in the second direction DR2 and may be spaced and/or apart (e.g., spaced apart or separated) from one another in the first direction DR1.

The non-display area NDA may be around (e.g., surround) the display area DA. The gate driver 210, fan-out lines FOL, and gate control lines GCL may be located in the non-display area NDA. The gate driver 210 may generate a plurality of gate signals based on the gate control signal, and may sequentially supply the plurality of gate signals to the plurality of gate lines GL in a set or predetermined order.

The fan-out lines FOL may extend from the display driver 200 to the display area DA. The fan-out lines FOL may provide the data voltage received from the display driver 200 to the plurality of data lines DL.

A gate control line GCL may extend from the display driver 200 to the gate driver 210. The gate control line GCL may supply the gate control signal received from the display driver 200 to the gate driver 210.

The subsidiary area SBA may include the display driver 200, a pad area PA, and first and second touch pad areas TPA1 and TPA2.

The display driver 200 may output signals and voltages to the fan-out lines FOL for driving the display panel 100. The display driver 200 may supply data voltages to the data lines DL through the fan-out lines FOL. The data voltages may be applied to the plurality of pixels PX, so that the luminance of the plurality of pixels PX may be controlled or driven. The display driver 200 may supply a gate control signal to the gate driver 210 through the gate control lines GCL.

The pad area PA, the first touch pad area TPA1 and the second touch pad area TPA2 may be located at the edge of the subsidiary area SBA. The pad area PA, the first touch pad area TPA1 and the second touch pad area TPA2 may be electrically connected to the circuit board 300 using an adhesive material.

The pad area PA may include a plurality of display pads DP. The plurality of display pads DP may be connected to a graphic system through the circuit board 300. The plurality of display pads DP may be connected to the circuit board 300 to receive digital video data and may supply the digital video data to the display driver 200.

The first and second touch pad areas TPA1 and TPA2 may include first pads TP1 and second touch pads TP2, respectively. The first and second touch pads TP1 and TP2 may be connected to the touch driver 400 through the circuit board 300. The first and second touch pads TP1 and TP2 may be connected to the touch driver 400 through the circuit board 300 and may receive touch driving signals.

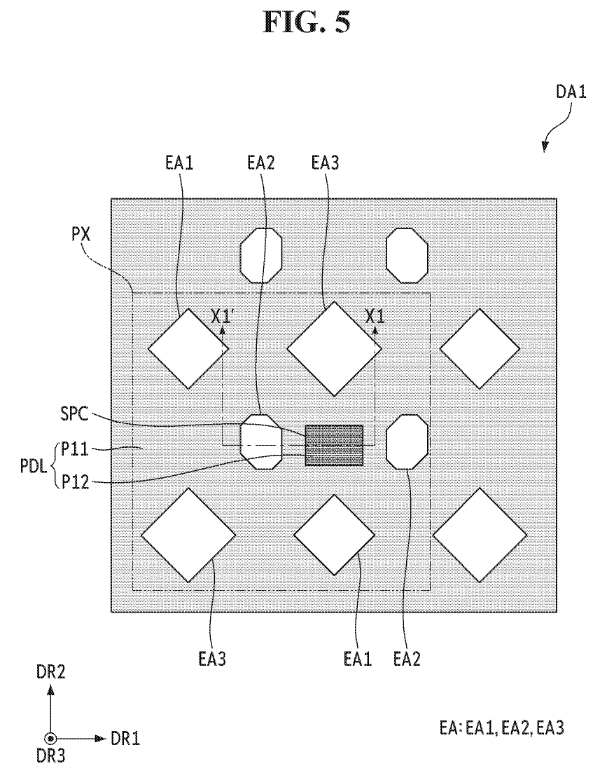

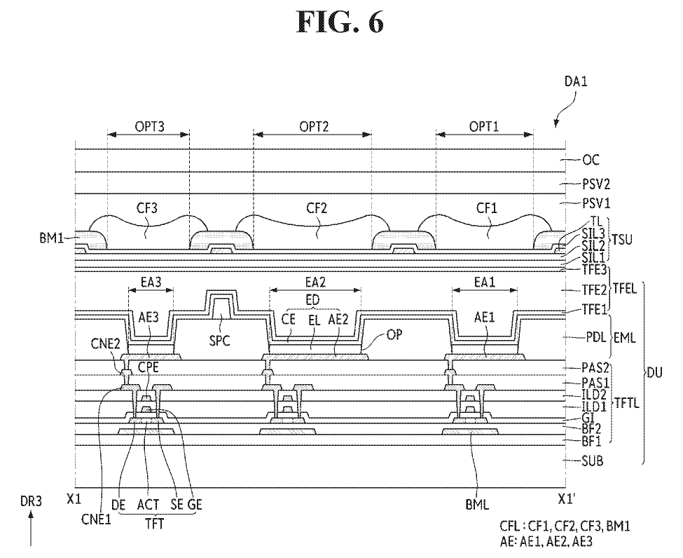

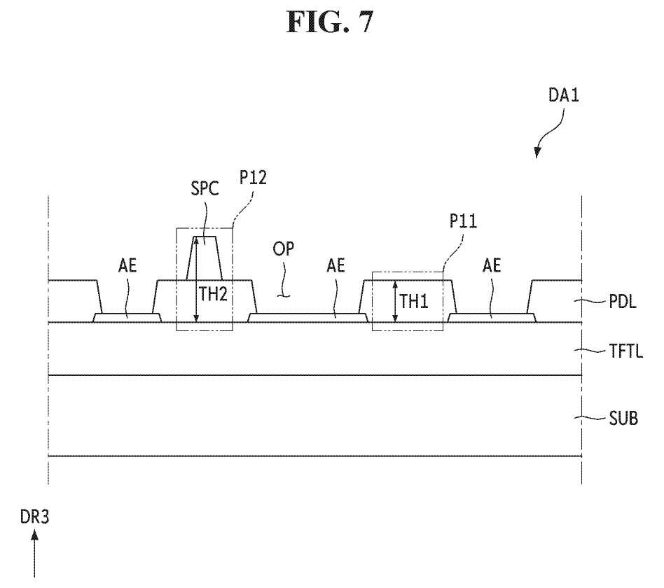

FIG. 5 is a plan view showing a part of a first display area of a display device according to one or more embodiments of the present disclosure. FIG. 6 is a cross-sectional view taken along the line X1 – X1' in FIG. 5, according to one or more embodiments of the present disclosure. FIG. 7 is a cross-sectional view showing a part of a first display area of a display device according to one or more embodiments of the present disclosure.

Referring to FIGS. 5-7, the first display area DA1 may include a plurality of pixels PX. Although only one or more pixels PX are depicted in the drawings, a plurality of pixels PX may be repeatedly arranged throughout the first display area DA1 along the first direction DR1 and the second direction DR2.

Each of the plurality of pixels PX may include a plurality of emission areas EA. For example, each of the plurality of pixels PX may include a first emission area EA1, a second emission area EA2, and a third emission area EA3.

Although a single pixel PX including two first emission areas EA1, two second emission areas EA2, and two third emission areas EA3 is shown in FIG. 5, the present disclosure is not limited thereto. The number of first emission areas EA1, second emission areas EA2 and third emission areas EA3 included in one pixel PX may each vary. For example, the number of first emission areas EA1, second emission areas EA2 and third emission areas EA3 may be different from one another.

A pixel PX may include one or more light-emitting elements ED. In one or more embodiments, one or more light-emitting elements ED included in a pixel PX may be to emit the same color or different colors. For example, a light-emitting element ED located in the first emission area EA1 may be to emit a red first light, a light-emitting element ED located in the second emission area EA2 may be to emit a green second color light, and a light-emitting element ED located in the third emission area EA3 may be to emit a blue third color light. It is, however, to be understood that the present disclosure is not limited thereto.

According to one or more embodiments, in each of the emission areas EA1, EA2 and EA3 of the display device 10, an emissive layer EL may overlap with a pixel electrode AE. Openings OP of the pixel-defining layer PDL may be associated with the emission areas EA1, EA2 and EA3. For example, the emission areas EA1, EA2 and EA3 may be defined by the openings OP of the pixel-defining layer PDL of the emission material layer EML, respectively. In the first emission area EA1, an emissive layer EL may overlap with a first pixel electrode AE1. In the second emission area EA2, the emissive layer EL may overlap with a second pixel electrode AE2. In the third emission area EA3, the emissive layer EL may overlap with a third pixel electrode AE3.

According to one or more embodiments, the plurality of emission areas EA may be arranged in a PenTile^{®} matrix (for example, an RGBG matrix, an RGBG structure, or RGBG matrix structure) or a diamond matrix (Diamond Pixel^{®}) (e.g., a display (e.g., an OLED display) containing red, blue, and green (RGB) light emitting regions arranged in the shape of diamonds). PENTILE^{® and} Diamond Pixel^{®} are duly registered trademarks of Samsung Display Co., Ltd. For example, the first emission area EA1 and the third emission area EA3 are spaced and/or apart (e.g., spaced apart or separated) from each other in the first direction DR1 and the second direction DR2, and may be arranged alternately in the first direction DR1 and the second direction DR2. The second emission areas EA2 may be spaced and/or apart (e.g., spaced apart or separated) from each other in the first direction DR1 and the second direction DR2. The first emission area EA1 and the second emission area EA2 may be arranged alternately along a diagonal direction defined by the first direction DR1 and the second direction DR2 (e.g., a first diagonal direction) or a diagonal direction defined by the first direction DR1 and the opposite direction of the second direction DR2 (e.g., a second diagonal direction). The second emission area EA2 and the third emission area EA3 may be arranged alternately along the first diagonal direction or the second diagonal direction. It should be noted that the arrangement of the plurality of emission areas EA is not limited thereto and may be variously modified.

According to one or more embodiments, the emission areas EA may have different areas or sizes. In the example shown in FIG. 5, the area or size of the second emission area EA2 may be smaller than the area or size of the first emission area EA1 and the area or size of the first emission area EA3, and the area or size of the first emission area EA1 may be smaller than the area or size of the third emission area EA3. The intensity of output light may vary depending on the area of each of the emission areas EA. The colors of the images displayed on the display device 10 or the electronic device 1 may be controlled or selected by adjusting the area of each of the emission areas EA. The present disclosure is not limited to the areas or sizes of the emission areas EA shown in FIG. 5. The size and area of each of the emission areas EA may be adjusted as desired or suitable according to the colors of the images desired or required by the display device 10 and the electronic device 1. In addition, the size of each of the emission areas EA may be related to light efficiency, lifespan of the light-emitting elements ED, and/or the like, and may have a trade-off relationship with reflection of external light. The size of each of the emission areas EA may be adjusted by taking the above factors into account.

According to one or more embodiments, the emission areas EA may have the same shape or different shapes. For example, as shown in FIG. 5, the first emission area EA1 and the third emission area EA3 may have a diamond shape, and the second emission area EA2 may have an octagonal shape. It is, however, to be understood that the present disclosure is not limited thereto. The shape of the emission areas EA may be modified in a variety of ways.

The display panel 100 may include a display layer DU, a touch sensing layer TSU, a color filter layer CFL, passivation layers PSV1 and PSV2, and an overcoat layer OC. The display layer DU may include a substrate SUB, a thin-film transistor layer TFTL, an emission material layer EML and an encapsulation layer TFEL. The color filter layer CFL may include a first light-blocking layer BM1 and color filters CF1, CF2 and CF3.

The substrate SUB may be a base substrate or a base member. The substrate SUB may be a flexible substrate that can be bent, folded, or rolled. For example, the substrate SUB may include, but is not limited to, a polymer resin such as polyimide PI. For another example, the substrate SUB may include a glass material or a metal material.

The thin-film transistor layer TFTL may include a first buffer layer BF1, a bottom metal layer BML, a second buffer layer BF2, a thin-film transistor TFT, a gate insulator GI, a first interlayer dielectric layer ILD1, a capacitor electrode CPE, a second interlayer dielectric layer ILD2, a first connection electrode CNE1, a first passivation layer PAS1, a second connection electrode CNE2 and a second passivation layer PAS2.

The first buffer layer BF1 may be located on the substrate SUB. The first buffer layer BF1 may include an inorganic film capable of preventing or reducing permeation of air or moisture. For example, the first buffer layer BF1 may include a plurality of inorganic films stacked on one another alternately.

The bottom metal layer BML may be located on the first buffer layer BF1. For example, the bottom metal layer BML may be made up of a single layer or multiple layers of at least one of molybdenum (Mo), aluminum (Al), chromium (Cr), gold (Au), titanium (Ti), nickel (Ni), neodymium (Nd) and/or copper (Cu) or one or more alloys thereof.

The second buffer layer BF2 may cover the first buffer layer BF1 and the bottom metal layer BML. The second buffer layer BF2 may include an inorganic film capable of preventing or reducing permeation of air or moisture. For example, the second buffer layer BF2 may include a plurality of inorganic films stacked on one another alternately.

The thin-film transistor TFT may be located on the second buffer layer BF2 and may form a pixel circuit of each of a plurality of pixels. For example, the thin-film transistor TFT may be a driving transistor or a switching transistor of the pixel circuit. The thin-film transistor TFT may include a semiconductor layer ACT, a source electrode SE, a drain electrode DE and a gate electrode GE.

The semiconductor layer ACT may be located on the second buffer layer BF2. The semiconductor layer ACT may overlap the bottom metal layer BML and the gate electrode GE in the thickness direction and may be insulated from the gate electrode GE by the gate insulator GI. The material of a part of the semiconductor layer ACT may be made conductive to form the source electrode SE and the drain electrode DE.

The gate electrode GE may be located on the gate insulator GI. The gate electrode GE may overlap with the semiconductor layer ACT with the gate insulating layer GI between the gate electrode GE and the semiconductor layer ACT.

The gate insulator GI may be located on the semiconductor layer ACT. For example, the gate insulator GI may cover the semiconductor layer ACT and the second buffer layer BF2, and may insulate the semiconductor layer ACT from the gate electrode GE. The gate insulator GI may include a contact hole through which the first connection electrode CNE1 passes.

The first interlayer dielectric layer ILD1 may cover the gate electrode GE and the gate insulator GI. The first interlayer dielectric layer ILD1 may include a contact hole through which the first connection electrode CNE1 passes. The contact holes of the first interlayer dielectric layer ILD1 may be connected to the contact holes of the gate insulator GI and the contact holes of the second interlayer dielectric layer ILD2.

The capacitor electrode CPE may be placed on the first interlayer dielectric layer ILD1. The capacitor electrode CPE may overlap with the gate electrode GE in the thickness direction. The capacitor electrode CPE and the gate electrode GE may form a capacitance.

The second interlayer dielectric layer ILD2 may cover the capacitor electrode CPE and the first interlayer dielectric layer ILD1. The second interlayer dielectric layer ILD2 may include a contact hole through which the first connection electrode CNE1 passes. The contact hole of the second interlayer dielectric layer ILD2 may be connected to the contact hole of the first interlayer dielectric layer ILD1 and the contact hole of the gate insulator GI.

The first connection electrode CNE1 may be located on the second interlayer dielectric layer ILD2. The first connection electrode CNE1 may electrically connect the drain electrode DE of the thin-film transistor TFT with the second connection electrode CNE2. The first connection electrode CNE1 may be inserted into a contact hole formed in the second interlayer dielectric layer ILD2, the first interlayer dielectric layer ILD1, and the gate insulator GI to be in contact with the drain electrode DE of the thin-film transistor TFT.

The first passivation layer PAS1 may cover the first connection electrode CNE1 and the second interlayer dielectric layer ILD2. The first passivation layer PAS1 can protect the thin-film transistor TFT. The first passivation layer PAS1 may include a contact hole through which the second connection electrode CNE2 passes.

The second connection electrode CNE2 may be located on the first passivation layer PAS1. The second connection electrode CNE2 may electrically connect the first connection electrode CNE1 with a pixel electrode AE of the light-emitting element ED. The second connection electrode CNE2 may be inserted into a contact hole formed in the first passivation layer PAS1 to be in contact with the first connection electrode CNE1.

The second passivation layer PAS2 may cover the second connection electrode CNE2 and the first passivation layer PAS1. The second passivation PAS2 may include a contact hole through which the pixel electrode AE of the light-emitting diode ED passes.

The emission material layer EML may be located on the thin-film transistor layer TFTL. The emission material layer EML may include a light-emitting element ED and a pixel-defining layer PDL. The light-emitting diode ED may include the anode electrode AE, an emissive layer EL, and a common electrode CE.

The pixel electrode AE may be located on the second passivation layer PAS2. Different pixel electrodes AE may be arranged such that they overlap different openings OP of the pixel-defining layer PDL, respectively. The pixel electrode AE may be electrically connected to the drain electrode DE of the thin-film transistor TFT through the first and second connection electrodes CNE1 and CNE2.

The emissive layer EL may be located on the pixel electrode AE. For example, the emissive layer EL may be, but is not limited to, an organic emissive layer made of an organic material. If the emissive layer EL is an organic emissive layer, if (e.g., when) the thin-film transistor applies a set or predetermined voltage to the pixel electrode AE of the light-emitting diode ED and the common electrode CE of the light-emitting diode ED receives a common voltage or cathode voltage, the holes and electrons may move to the emissive layer EL through the hole transporting layer and the electron transporting layer, respectively, and they combine in the emissive layer EL to emit light.

According to one or more embodiments, the emissive layers EL respectively arranged on different pixel electrodes AE may be to emit light of different colors. For example, the emissive layer located on the first pixel electrode AE1 may be to emit red light of the first color, the emissive layer located on the second pixel electrode AE2 may be to emit green light of the second color, and the emissive layer located on the third pixel electrode AE3 may be to emit blue light of the third color. It is, however, to be understood that the present disclosure is not limited thereto. According to one or more embodiments, the emissive layer EL may be placed as a single common layer on the different pixel electrodes AE and the pixel-defining layer PDL. The emissive layer placed on the different pixel electrodes AE may be to emit light of the same color. In this instance, the display device 10 may further include a color adjustment layer placed on the light-emitting elements ED.

The common electrode CE may be arranged on the emissive layer EL. For example, the common electrode CE may be implemented as an electrode common to all pixels, instead of being located as a separated electrode for each of the pixels. The common electrode CE may be located on the emissive layer EL on the pixel electrodes AE and may be located on the pixel-defining layer PDL around the pixel electrodes AE.

The common electrode CE may receive a common voltage or a low-level voltage. When the pixel electrode AE receives the voltage equal to the data voltage and the common electrode CE receives the low-level voltage, a potential difference is formed between the pixel electrode AE and the common electrode CE, so that the emissive layer EL can emit light.

The pixel-defining layer PDL may include a plurality of openings OP and may be placed on the second passivation layer PAS2 and a part of the pixel electrode AE. The openings OP of the pixel-defining layer PDL may partially expose the pixel electrodes AE. As described above, the openings OP of the pixel-defining layer PDL may define the respective emission areas EA, and they may have different areas or sizes. The pixel-defining layer PDL may separate and insulate the pixel electrodes AE of each of the plurality of light-emitting elements ED from each of the remaining pixel electrodes of other light-emitting elements ED.

The pixel-defining layer PDL may include a light-absorbing material to prevent or reduce light reflection. For example, the pixel-defining layer PDL may include a polyimide (PI)-based binder, and pigments in which red, green and blue are mixed. In one or more embodiments, the pixel-defining layer PDL may include a cardo-based binder resin and/or a (e.g., any suitable) mixture of lactam black pigment and blue pigment. In one or more embodiments, the pixel-defining layer PDL may include carbon black.

The pixel-defining layer PDL may include partition walls and a spacer SPC. The partition walls may define a plurality of openings OP. The spacer SPC may be arranged on some of the partition walls defining the openings OP of the pixel-defining layer PDL. The spacer SPC may include at least one organic insulating layer containing an organic insulating material. According to one or more embodiments, the spacer SPC may include the same material as the pixel-defining layer PDL. The pixel-defining layer PDL and the spacer SPC may be formed sequentially via respective mask processes, or may be formed concurrently (e.g., simultaneously) and/or integrally using a halftone mask (see, e.g., FIG. 19).

The encapsulation layer TFEL may be located on the common electrode CE to cover the light-emitting elements ED. The encapsulation layer TFEL may include at least one inorganic layer to prevent or reduce permeation of oxygen or moisture into the emission material layer EML. The encapsulation layer TFEL may include at least one organic layer to protect the emission material layer EML from foreign substances such as dust.

According to one or more embodiments of the present disclosure, the encapsulation layer TFEL may include a first encapsulation layer TFE1, a second encapsulation layer TFE2 and a third encapsulation layer TFE3. The first encapsulation layer TFE1 and the third encapsulation layer TFE3 may be inorganic encapsulation layers, and the second encapsulation layer TFE2 between the first encapsulation layer TFE1 and the third encapsulation layer TFE3 may be an organic encapsulation layer.

Each of the first encapsulation layer TFE1 and the third encapsulation layer TFE3 may include one or more inorganic insulating materials. The inorganic insulating material may include aluminum oxide, titanium oxide, tantalum oxide, hafnium oxide, zinc oxide, silicon oxide, silicon nitride, and/or silicon oxynitride.

The second encapsulation layer TFE2 may include a polymer-based material. The polymer-based material may include an acrylic resin, an epoxy resin, polyimide, polyethylene, and/or the like. For example, the second encapsulation layer TFE2 may include an acrylic resin, e.g., polymethyl methacrylate, polyacrylic acid, and/or the like. The second encapsulation layer TFE2 may be formed by curing a monomer or by applying a polymer.

The touch sensing layer TSU may be located on the encapsulation layer TFEL. The touch sensing layer TSU may include a first touch insulating layer SIL1, a second touch insulating layer SIL2, touch electrodes TL, and a third touch insulating layer SIL3.

The first touch insulating layer SIL1 may be located on the encapsulation layer TFEL. The first touch insulating layer SIL1 may have insulating properties and optical features. The first touch insulating layer SIL1 may include at least one inorganic film. In one or more embodiments, the first touch insulating layer SIL1 may not be provided.

The second touch insulating layer SIL2 may cover the first touch insulating layer SIL1. In one or more embodiments, a touch electrode of another layer may be further located on the first touch insulating layer SIL1, and the second touch insulating layer SIL2 may cover such a touch electrode. The second touch insulating layer SIL2 may have insulating properties and optical features. For example, the second touch insulating layer SIL2 may be an inorganic layer including at least one selected from the group consisting of: a silicon nitride layer, a silicon oxynitride layer, a silicon oxide layer, a titanium oxide layer and an aluminum oxide layer.

Some of the touch electrodes TE may be located on the second touch insulating layer SIL2. The touch electrodes TL may not overlap with the pixel electrodes AE. Each of the touch electrodes TL may be made up of a single layer of molybdenum (Mo), titanium (Ti), copper (Cu), aluminum (Al), or indium tin oxide (ITO), or may be made up of a stack structure of aluminum and titanium (Ti/Al/Ti), a stack structure of aluminum and ITO (ITO/Al/ITO), an APC alloy and/or a stack structure of an APC alloy and ITO (ITO/APC/ITO).

The touch electrodes TL of the touch sensing layer TSU may have a constant line width and may overlap a first light-blocking layer BM1 to be described in more detail later. The first light-blocking layer BM1 may have a width sufficient to completely cover the touch electrodes TL. A gap between an edge of the first light-blocking layer BM1 and the touch electrodes TL may be defined. The touch electrodes TL may be arranged such that their centers are generally in line with the centers of the first light-blocking layer BM1, and the distance from the opposite sides of the touch electrodes TL to the edges of the first light-blocking layer BM1 may be substantially constant.

The third touch insulating layer SIL3 may cover the touch electrodes TL and the second touch insulating layer SIL2. The third touch insulating layer SIL3 may have insulating properties and optical features. The third touch insulating layer SIL3 may be made of one of the above-listed materials included as the material of the second touch insulating layer SIL2.

The first light-blocking layer BM1 may include a light-absorbing material. For example, the first light-blocking layer BM1 may include an inorganic black pigment or an organic black pigment. The inorganic black pigment may be, but is not limited to, carbon black, and the organic black pigment may include, but is not limited to, at least one of lactam black, perylene black, and/or aniline black.

The first light-blocking layer BM1 may be placed on the third touch insulating layer SIL3 of the touch sensing layer TSU. The first light-blocking layer BM1 may cover a conductive line of the touch electrodes TL and may include a plurality of holes OPT1, OPT2 and OPT3 arranged in line with (and/or overlapping) the pixel electrodes AE3. For example, the first hole OPT1 may be in line with (and/or overlapping) the first pixel electrode AE1, the second hole OPT2 may be in line with (and/or overlapping) the second pixel electrode AE2, and the third hole OPT3 may be in line with (and/or overlapping) the third pixel electrode AE3. The area or size of each of the holes OPT1, OPT2 and OPT3 may be larger than the area or size of the pixel electrodes AE. In one or more embodiments, the area or size of each of the holes OPT1, OPT2 and OPT3 may be larger than that of each of the openings OP of the pixel-defining layer PDL. As such, the lights emitted from the light-emitting elements ED may be recognized by the user not only from the front but also from the sides of the display device 10.

The color filters CF1, CF2 and CF3 may be arranged on the first light-blocking layer BM1. The color filters CF1, CF2 and CF3 may be associated with the emission areas EA1, EA2 and EA3, respectively. For example, the first color filter CF1 may be in line with (and/or overlapping) the first emission area EA1, the second color filter CF2 may be in line with (and/or overlapping) the second emission area EA2, and the third color filter CF3 may be in line with (and/or overlapping) the third emission area EA3. The color filters CF1, CF2 and CF3 may be associated with the holes OPT1, OPT2 and OPT3 of the first light-blocking layer BM1. For example, the first color filter CF1 may be in line with (and/or overlapping) the first hole OPT1, the second color filter CF2 may be in line with (and/or overlapping) the second hole OPT2, and the third color filter CF3 may be in line with (and/or overlapping) the third hole OPT3.

The color filters CF1, CF2 and CF3 may completely cover the emission areas EA1, EA2 and EA3. The color filters CF1, CF2 and CF3 may completely cover the holes OPT1, OPT2 and OPT3 of the first light-blocking layer BM1, respectively. For example, each of the color filters CF1, CF2 and CF3 may have a width larger than widths of each of the emission areas EA1, EA2 and EA3 and widths of each of the holes OPT1, OPT2 and OPT3 of the first light-blocking layer BM1, respectively. Accordingly, the color filters CF1, CF2 and CF3 may completely cover the areas in which lights output from the emission areas EA1, EA2 and EA3 exit through the holes OPT1, OPT2 and OPT3 of the first light-blocking layer BM1.

The color filters CF1, CF2 and CF3 include a first color filter CF1, a second color filter CF2 and a third color filter CF3 associated with the different emission areas EA1, EA2 and EA3, respectively. The color filters CF1, CF2 and CF3 may include a colorant such as a dye and/or pigment that absorbs light in wavelength ranges other than light in a particular wavelength range, and may be arranged in association with the colors of the lights exiting from the light-emitting elements including the emission areas EA1, EA2 and EA3. For example, the first color filter CF1 may be a red color filter arranged to overlap the first emission area EA1 and transmitting only the red first light, the second color filter CF2 may be a green color filter arranged to overlap the second emission area EA2 and transmitting only the green second light, and the third color filter CF3 may be a blue color filter arranged to overlap the third emission area EA3 and transmitting only the blue third light.

The passivation layers PSV1 and PSV2 may be arranged over the first light-blocking layer BM1 and the color filter layer CFL. The passivation layers PSV1 and PSV2 may be arranged throughout the display area DA to provide a flat upper surface of the display panel 100. The passivation layers PSV1 and PSV2 may include a first passivation layer PSV1 located on the color filter layer CFL and the first light-blocking layer BM1, and a second passivation layer PSV2 located on the first passivation layer PSV1. The passivation layers PSV1 and PSV2 are made up of multiple layers and may provide a flat surface over the color filter layer CFL and the first light-blocking layer BM1 having different heights (e.g., an upper surface of each of the color filter layer CFL and the first light-blocking layer BM1 may be uneven, e.g., may have different heights, and the passivation layers PSV1 and PSV2 may cover these layers to provide a flat surface).

The passivation layers PSV1 and PSV2 may be a colorless light-transmitting layer having no color in the visible light range. For example, the passivation layers PSV1 and PSV2 may include a colorless light-transmitting organic material such as an acryl-based resin.

The overcoat layer OC may be placed on the passivation layers PSV1 and PSV2. The overcoat layer OC may be arranged throughout the display area DA to provide a flat upper surface of the display panel 100. The overcoat layer OC may be a colorless light-transmitting layer having no color in the visible light range. For example, the overcoat layer OC may include a colorless light-transmitting organic material such as an acryl resin.

The display device 10 according to one or more embodiments includes the color filter layer CFL, so that a portion of light entering from outside of the display device 10 can be absorbed in order to reduce reflected light due to external light. Accordingly, the color filter layer CFL can prevent or reduce distortion of colors due to the reflection of external light. In one or more embodiments, because no separate polarizing plate is desired or required to reduce the reflection of external light, the light emission efficiency of the display device 10 can be improved and costs may be reduced.

Incidentally, in order to reduce light reflection due to external light together with the color filter layer CFL, the pixel-defining layer PDL may contain a light-absorbing material to prevent or reduce light reflection, as described above. For example, the pixel-defining layer PDL may include a polyimide (PI)-based binder, and pigments in which red, green and blue are mixed. In one or more embodiments, the pixel-defining layer PDL may include a cardo-based binder resin and/or a (e.g., any suitable) mixture of lactam black pigment and blue pigment. In one or more embodiments, the pixel-defining layer PDL may include carbon black. As the pixel-defining layer PDL contains the light-absorbing material, it is possible to prevent or reduce the likelihood of external light being reflected by the conductive patterns and the lines arranged in the thin-film transistor layer TFTL and seen from the outside.

As shown in FIG. 7, in the first display area DA1, the pixel-defining layer PDL may include a first portion P11 and a second portion P12.

The first portion P11 may be a portion of the pixel-defining layer PDL having a first thickness TH1. In the first display area DA1, the first portion P11 may be a part of the partition walls that define the openings OP of the pixel-defining layer PDL. In the first display area DA1, the first portion P11 may not overlap the pixel electrode AE in the third direction DR3.

The second portion P12 may be a portion of the pixel-defining layer PDL having a second thickness TH2. In the first display area DA1, the second portion P12 may include a partition wall under a spacer SPC and the spacer SPC. In the first display area DA1, the second portion P12 may not overlap the pixel electrode AE in the third direction DR3.

The second thickness TH2 may be greater than the first thickness TH1. According to one or more embodiments, the first thickness TH1 may be approximately 1 μm to 2 μm, for example, approximately 1.5 μm. According to one or more embodiments, the second thickness TH2 may be approximately 2.5 μm to 3.5 μm, for example, approximately 3 μm. The first thickness TH1 and the second thickness TH2 refer to the distances in the third direction DR3 from the lower surface to the upper surface of the pixel-defining layer PDL.

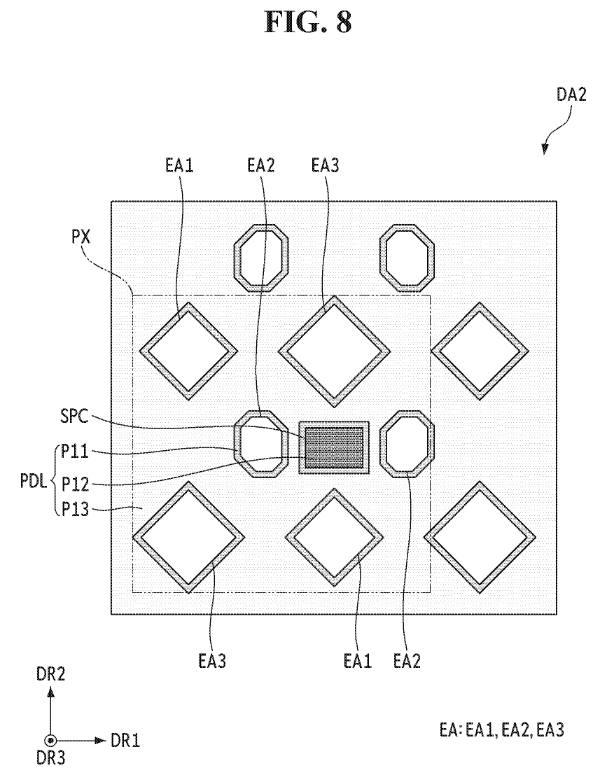

As shown in FIG. 5, in the first display area DA1, the first portion P11 may be located in the remaining area of the first display area DA1 excluding the emission area EA and the second portion P12 when viewed from the top(e.g., in a plan view). In the first display area DA1, the second portion P12 may be placed at the area where the spacer SPC is located. For example, if the spacer SPC is located between the second emission areas EA2 in the first direction DR1 and between the first emission area EA1 and the third emission area EA3 in the second direction DR2, the second portion P12 may be located between the second emission areas EA2 in the first direction DR1 and between the first emission area EA1 and the third emission area EA3 in the second direction DR2. A third portion P13 may be around (e.g., surround) the first portion P11 and the second portion P12 when viewed from the top (e.g., in a plan view, see, e.g., FIG. 8).

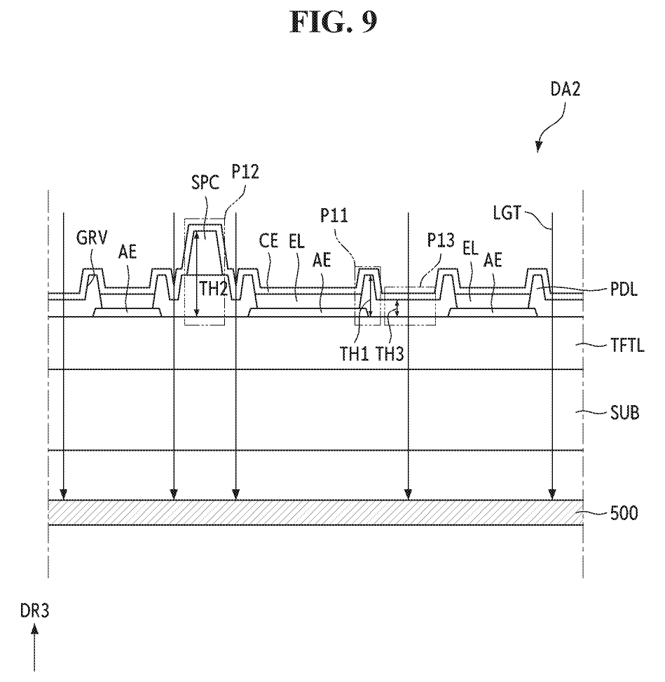

FIG. 8 is a plan view showing a part of the second display area of the display device according to one or more embodiments of the present disclosure. FIG. 9 is a cross-sectional view showing a part of the second display area and an optical device of the display device according to one or more embodiments of the present disclosure.

Referring to FIGS. 8 and 9 in conjunction with FIG. 6, the second display area DA2 may include a plurality of pixels PX. Each of the plurality of pixels PX may include a plurality of emission areas EA. The arrangements and shapes of the pixels PX, the emission areas EA and the spacer SPC in the second display area DA2 are substantially identical to those of the pixels PX, the emission areas EA and the spacer SPC in the first display area DA1 described above with reference to FIG. 5; and, therefore, the redundant descriptions may not be provided.

In the second display area DA2, the pixel-defining layer PDL may include a first portion P11, a second portion P12, and a third portion P13.

The first portion P11 may be a portion of the pixel-defining layer PDL having a first thickness TH1. In the second display area DA2, the first portion P11 may be a part of the partition walls that define the openings OP of the pixel-defining layer PDL. In the second display area DA2, the first portion P11 may overlap with the pixel electrode AE in the third direction DR3. For example, in the first display area DA1, the first portion P11 does not overlap the pixel electrode AE in the third direction DR3; by contrast, in the second display area DA2, the first portion P11 may overlap the pixel electrode AE in the third direction DR3.

The second portion P12 may be a portion of the pixel-defining layer PDL having a second thickness TH2. In the second display area DA2, the second portion P12 may include a partition wall under a spacer SPC and the spacer SPC. In the second display area DA2, the second portion P12 may not overlap with the pixel electrode AE in the third direction DR3.

The third portion P13 may be a portion of the pixel-defining layer PDL having a third thickness TH3. In the second display area DA2, the third portion P13 may be in line with (and/or overlap) a groove GRV of the pixel-defining layer in the third direction DR3. The groove GRV may be a portion of the upper surface of the partition wall of the pixel-defining layer PDL that is recessed toward the substrate SUB. In the second display area DA2, the third portion P13 may not overlap with the pixel electrode AE in the third direction DR3.

The second thickness TH2 may be greater than the first thickness TH1, and the third thickness TH3 may be less than the first thickness TH1. According to one or more embodiments, the first thickness TH1 may be approximately 1 μm to 2 μm, for example, approximately 1.5 μm. According to one or more embodiments, the second thickness TH2 may be approximately 2.5 μm to 3.5 μm, for example, approximately 3 μm. According to one or more embodiments, the third thickness TH3 may be equal to or less than approximately 0.5 μm. The first thickness TH1, the second thickness TH2 and the third thickness TH3 refer to the distances in the third direction DR3 from the lower surface to the upper surface of the pixel-defining layer PDL.

As shown in FIG. 8, in the second display area DA2, the first portion P11 may be around (e.g., surround) the emission areas EA and the second portion P12 when viewed from the top (e.g., in a plan view). In the second display area DA2, the first portion P11 may be arranged along the borders of the emission areas EA and the second portion P12 with a width. In the second display area DA2, the second portion P12 may be placed at the area where the spacer SPC is located when viewed from the top (e.g., in a plan view). In the second display area DA2, the third portion P13 may be placed in the remaining area of the second display area DA2 excluding the emission areas EA, the first portion P11 and the second portion P12 when viewed from the top (e.g., in a plan view).

According to one or more embodiments, the common electrode CE may be formed conformally along (e.g., may conform to the shape of) the upper surface and the side surfaces of the pixel-defining layer PDL. For example, the common electrode CE may include a crest and a trough along the shapes of the groove GRV and the opening OP of the pixel-defining layer PDL. In one or more embodiments, the first encapsulation layer TFE1 may also be formed conformally along (e.g., may conform to the shape of) the upper surface and the side surfaces of the pixel-defining layer PDL (or the upper surface and the side surfaces of the common electrode CE) like the common electrode (CE). The height differences created by the groove GRV and the opening OP of the pixel-defining layer PDL may become flat by the second encapsulation layer TFE2.

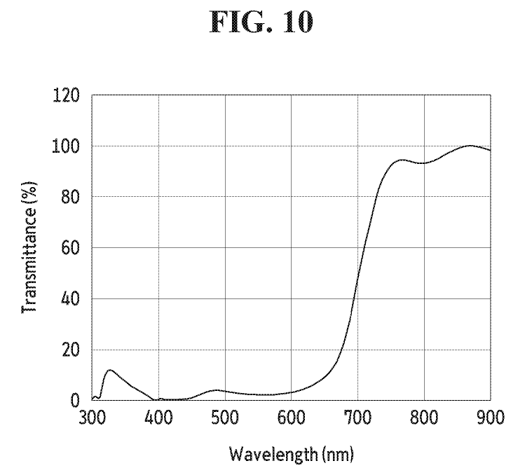

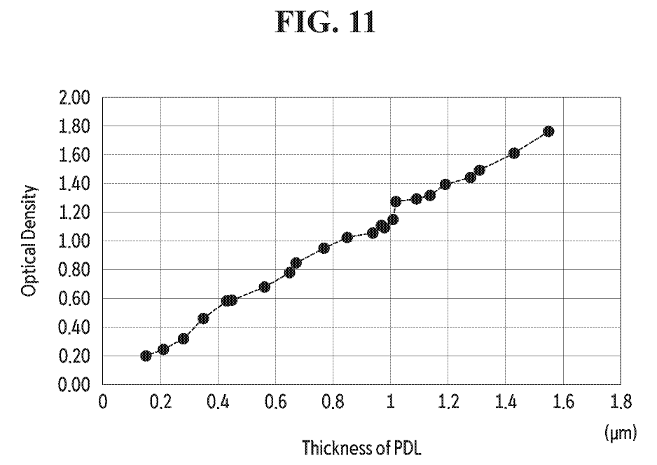

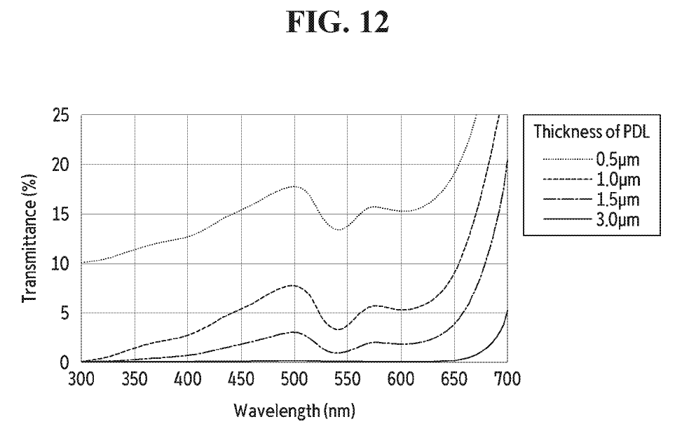

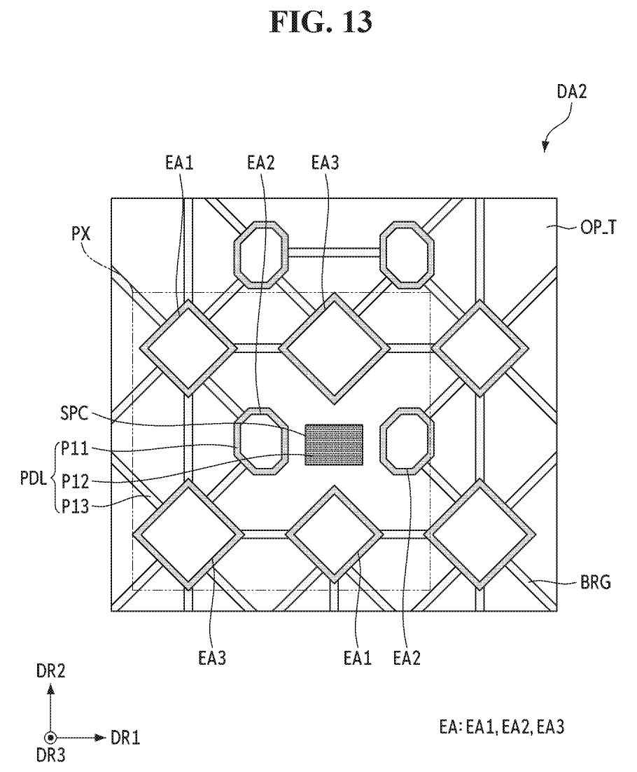

FIG. 10 is a graph showing the transmittance of the pixel-defining layer versus wavelength in the first display area of the display device according to one or more embodiments of the present disclosure. FIG. 11 is a graph showing the optical density of the pixel-defining layer versus thickness of the display device according to one or more embodiments of the present disclosure. FIG. 12 is a graph showing the transmittance of the pixel-defining layer versus wavelength of the display device for different thicknesses according to one or more embodiments of the present disclosure.

Referring to FIGS. 10-12 in conjunction with FIGS. 8 and 9, in the display device 10 according to one or more embodiments, the pixel-defining layer PDL includes the third portion P13, so that the transmittance of the display panel 100 and the amount of light incident on the optical device 500 can be increased.

For example, as shown in FIG. 10, in the first display area DA1, the transmittance of the pixel-defining layer PDL may have a significantly low value for light having a wavelength of approximately 650 nm or less. The optical device 500 may sense light having an infrared wavelength of 800 nm or more, but may also sense light having a visible light wavelength of 650 nm or less.

Therefore, in the second display area DA2 where the optical device 500 is placed, a higher transmittance is desired for visible light wavelengths of 650 nm or less relative to the first display area DA1.

As shown in FIG. 11, the smaller the thickness of the pixel-defining layer PDL is, the lower the optical density of the pixel-defining layer PDL is. For example, as shown in FIG. 12, for visible light of 650 nm or less, the transmittance of a pixel-defining layer PDL having the thickness of 1.5 μm is higher than that of a pixel-defining layer PDL having the thickness of 3.0 μm, the transmittance of a pixel-defining layer PDL having the thickness of 1.0 μm is higher than that of the pixel-defining layer PDL having the thickness of 1.5 μm, and the transmittance of a pixel-defining layer PDL having the thickness of 0.5 μm is higher than that of the pixel-defining layer PDL having the thickness of 1.0 μm.

Therefore, the display device 10 according to one or more embodiments includes the third portion P13 having the third thickness TH3, so that incident light LGT can be incident on the optical device 500 through the third portion P13, as shown in FIG. 9. Accordingly, the transmittance of the display panel 100 and the amount of light incident on the optical device 500 can be increased.

It should be noted that the display device 10 according to such embodiments can have higher durability compared to a display device in which there is no third portion P13 and a pixel-defining layer PDL is completely removed at the third portion P13. For example, if the pixel-defining layer PDL is completely removed from the area where the third portion P13 is located in order to increase the transmittance, the contact area between the pixel-defining layer PDL and the underlying layer may be reduced, such that the bonding strength may weaken. In contrast, in the display device 10 according to one or more embodiments, because the third portion P13 of the pixel-defining layer PDL is extended throughout the second display area DA2, the contact area between the pixel-defining layer PDL and the underlying layer may be increased, thereby increasing the bonding strength. Accordingly, it is possible to suppress or reduce the likelihood of the pixel-defining layer PDL lifting, so that the durability of the display device 10 can be improved.

Hereinafter, display devices according to one or more embodiments of the present disclosure will be described. In the following description, the same or similar elements will be denoted by the same or similar reference numerals, and redundant descriptions may not be provided or briefly described.

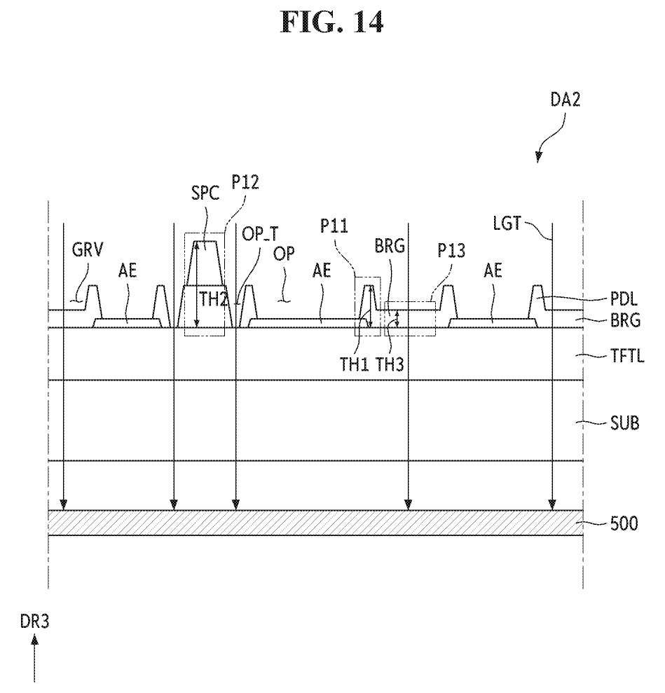

FIG. 13 is a plan view showing a part of a second display area of a display device according to one or more embodiments of the present disclosure. FIG. 14 is a cross-sectional view showing a part of the second display area and an optical device of the display device according to one or more embodiments of FIG. 13.

The display device 10 according to one or more embodiments of FIGS. 13 and 14 is different from the display device 10 according to the above-described embodiment of FIG. 8 and/or the like in that the former includes a transparent window OP_T and a bridge BRG.

More specifically, in the second display area DA2, the pixel-defining layer PDL may include a first portion P11, a second portion P12, and a third portion P13. The first portion P11, the second portion P12 and the third portion P13 are substantially identical to those of the above-described display device 10 of FIG. 8, etc.; and, therefore, the redundant descriptions may not be provided.

According to one or more embodiments, the second display area DA2 may further include the transparent window OP_T, and the pixel-defining layer PDL may further include the bridge BRG.

The transparent window OP_T may be a portion of the second display area DA2 where the pixel-defining layer PDL is not placed or located. In one or more embodiments, if (e.g., when) the common electrode CE is formed conformally along (e.g., conforms to the shape of) the upper surface and side surfaces of the pixel- defining layer PDL, the common electrode CE may be in direct contact with the upper surface of the thin-film transistor layer TFTL (e.g., the upper surface of the second passivation layer PAS2 of FIG. 6) at the transparent window OP_T. In the second display area DA2, the transparent window OP_T may be located in the remaining area of the second display area DA2 excluding the emission areas EA, the first portion P11, the second portion P12 and the third portion P13 when viewed from the top (e.g., in a plan view).

The display device 10 according to such embodiments can increased the transmittance of the display panel 100 and the amount of light incident on the optical device 500 by including the transparent window OP_T.

The bridge BRG may connect between the first portions P11 around (e.g., surrounding) the emission areas EA. The bridge BRG may connect between the adjacent first portions P11. The bridge BRG may have a width when viewed from the top (e.g., in a plan view). For example, the bridge BRG may have a width of approximately 10 µm or less when viewed from the top (e.g., in a plan view). The number, shape, arrangement, and/or the like, of the bridges BRG shown in the drawings are merely illustrative and may be modified in one or more suitable ways.

The bridge BRG may be formed as the third portion P13 of the pixel-defining layer PDL. For example, the bridge BRG may have the third thickness TH3 in the third direction DR3. Accordingly, it is possible to reduce a decrease in the transmittance in the transparent window OP_T, thereby improving the transmittance of the display panel 100 and the amount of light incident on the optical device 500.

Unlike the display device 10 according to one or more embodiments described above with reference to FIG. 8, in the second display area DA2, the third portion P13 may be placed in the remaining area of the second display area DA2 excluding the emission areas EA, the first portion P11, the second portion P12 and the transparent window OP_T when viewed from the top (e.g., in a plan view).

The display device 10 according to embodiments of FIGS. 13-14 can improve bonding strength by including the bridge BRG to increase the contact area between the pixel-defining layer PDL and the underlying layer. In this manner, it is possible to suppress or reduce the likelihood of the pixel-defining layer PDL lifting, so that the durability of the display device 10 can be improved.

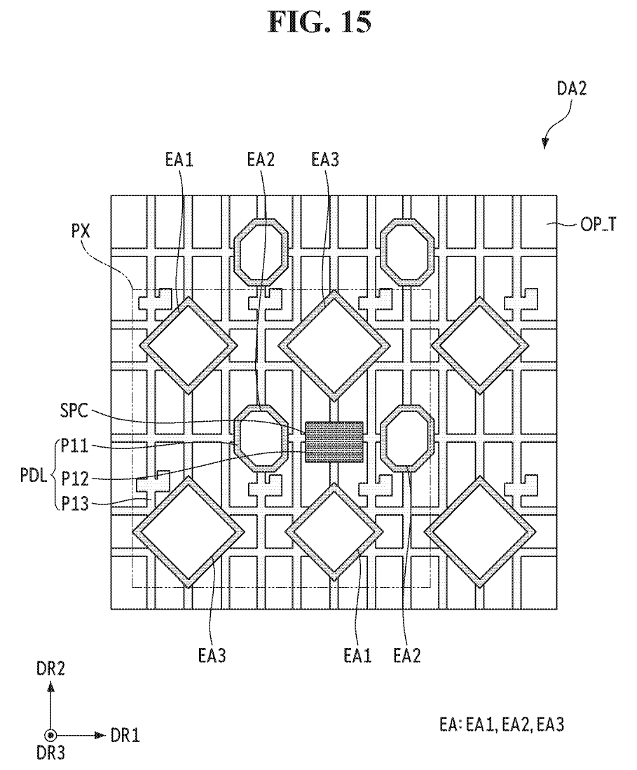

FIG. 15 is a plan view showing a part of a second display area of a display device according to one or more embodiments of the present disclosure.

Referring to FIG. 15 in conjunction with FIGS. 4 and 6, the display device 10 according to one or more embodiments is different from the display device 10 according to FIGS. 8, 13, etc., in that a third portion P13 overlaps the lines and the conductive patterns of a thin-film transistor layer TFTL in the third direction DR3.

More specifically, as described above with reference to FIG. 4, the display panel 100 may include a plurality of gate lines GL, a plurality of data lines DL, and a plurality of voltage lines VL arranged in the thin-film transistor layer TFTL in the display area DA. In one or more embodiments, the display panel 100 may further include a variety of transistors for driving the pixels PX.

As described above, as the pixel-defining layer PDL contains the light-absorbing material, it is possible to prevent or reduce the likelihood of external light being reflected by the conductive patterns and the lines arranged in the thin-film transistor layer TFTL and seen from the outside.

For example, the third portion P13 may be extended in the first direction DR1 along a gate line GL extended in the first direction DR1, and may be extended in the second direction DR2 along a data line DL extended in the second direction DR2. In one or more embodiments, the third portion P13 may overlap with the transistors arranged for each of the pixels PX. The arrangement of the third portion P13 shown in the drawings is merely illustrative and may be variously modified depending on the shapes of the conductive patterns and the lines of the thin-film transistor layer TFTL.

In the display device 10 according to such embodiments, the third portion P13 overlaps with the conductive patterns and the lines arranged in the thin-film transistor layer TFTL, so that reflection of external light can be reduced. At the same time, as the third portion P13 has the third thickness TH3, the transmittance of the display panel 100 and the amount of light incident on the optical device 500 can be increased.

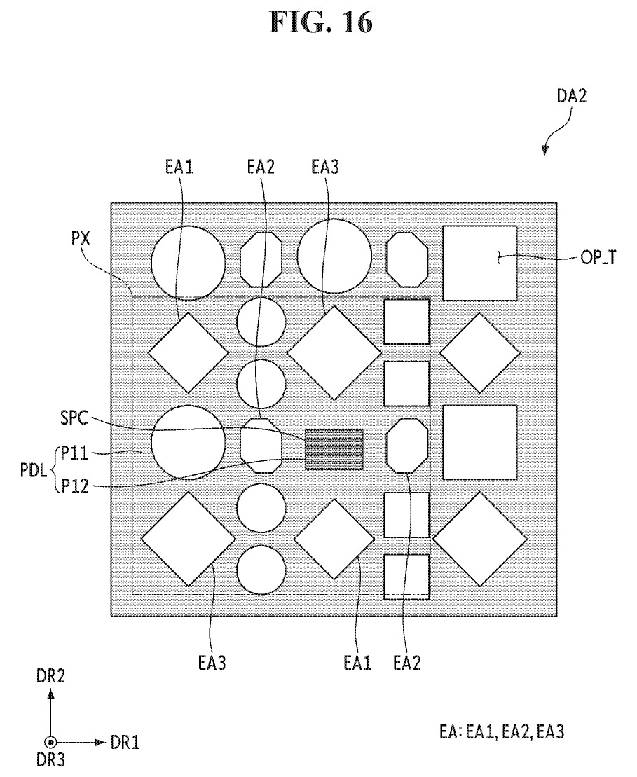

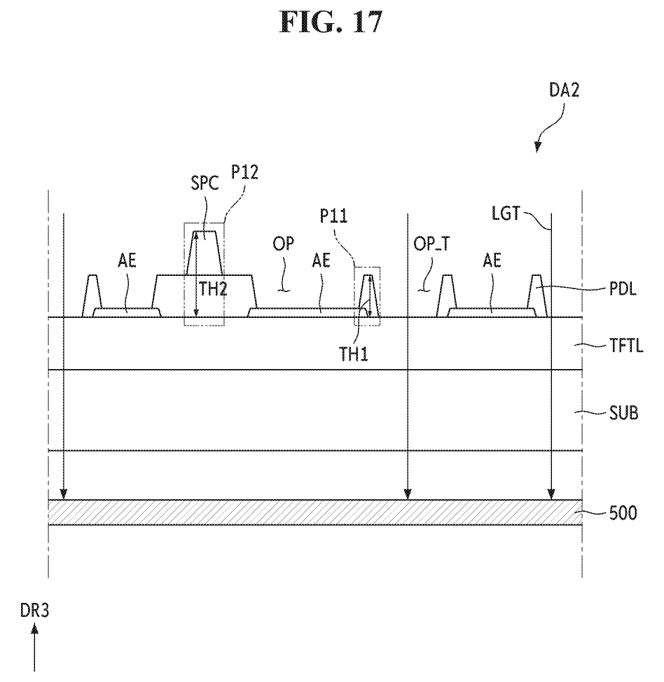

FIG. 16 is a plan view showing a part of a second display area of a display device according to one or more embodiments of the present disclosure. FIG. 17 is a cross-sectional view showing a part of the second display area and an optical device of the display device of FIG. 16, according to one or more embodiments of the present disclosure.

The display device 10 according to one or more embodiments of FIGS. 16 and 17 is different from the display device 10 according to FIGS. 8, 13, 15, etc., in that the former does not include a third portion P13 but includes a transparent window OP_T.

In one or more embodiments, a second display area DA2 of the display device 10 may not include (e.g., may exclude) the third portion P13, like the first display area DA1 of the display device 10 according to one or more embodiments described above with reference to FIG. 5 and 7, etc. That is to say, the pixel-defining layer PDL may include only the first portion P11 and the second portion P12 in the first display area DA1 and the second display area DA2.

However, unlike the first display area DA1, the second display area DA2 of the display device 10 according to one or more embodiments may include a transparent window OP_T.

The transparent window OP_T may be a closed region when viewed from the top (e.g., in a plan view). For example, as shown in, for example, FIG. 16, the transparent window OP_T may have a rectangular or circular shape. It should be understood, however, that the present disclosure is not limited thereto. The shape of the transparent window OP_T may be variously modified, and may include, for example, oval or other polygonal shapes.

The transparent window OP_T may be located between the emission areas EA. The area of the transparent window OP_T may be variously modified according to the amount of light incident on the optical device 500. According to one or more embodiments of the present disclosure, the size of the transparent window OP_T may be, but is not limited to, approximately 20 μm or less. The size of the transparent window OP_T refers to the length of the longest part in a direction (e.g., longest side or distance between opposite sides, or major axis (e.g., diameter)).

As shown in FIG. 16, in the second display area DA2, the first portion P11 may be located in the remaining area of the first display area DA1 excluding the emission areas EA, the transparent window OP_T and the second portion P12 when viewed from the top (e.g., in a plan view). In the second display area DA2, the second portion P12 may be placed at the area where the spacer SPC is located when viewed from the top (e.g., in a plan view).

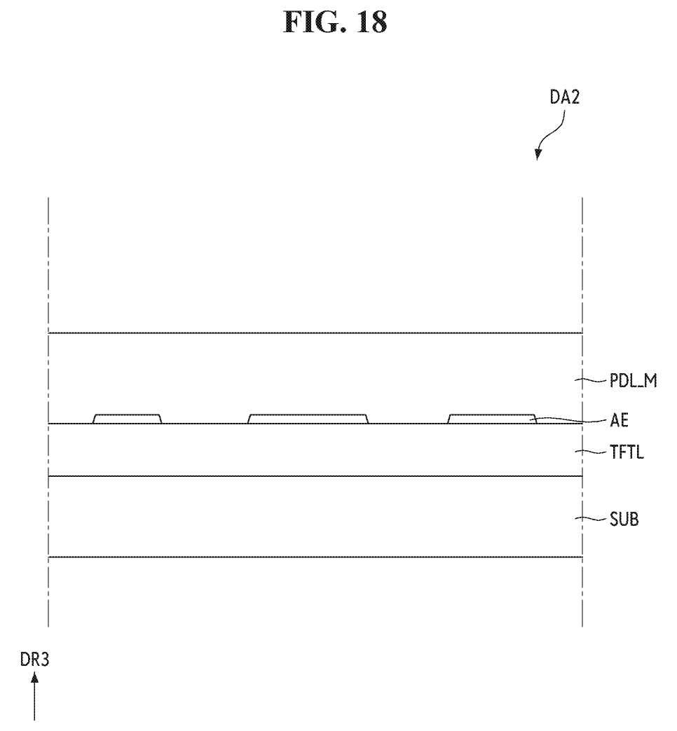

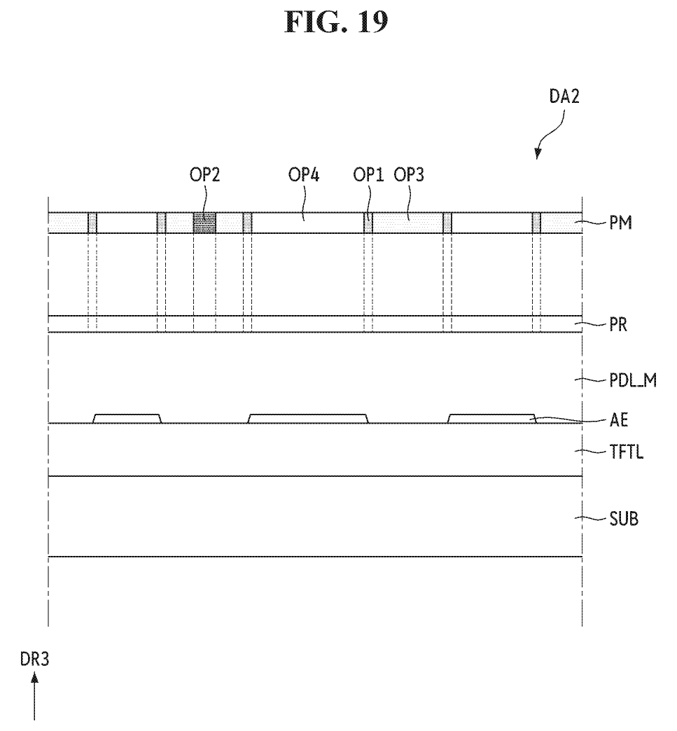

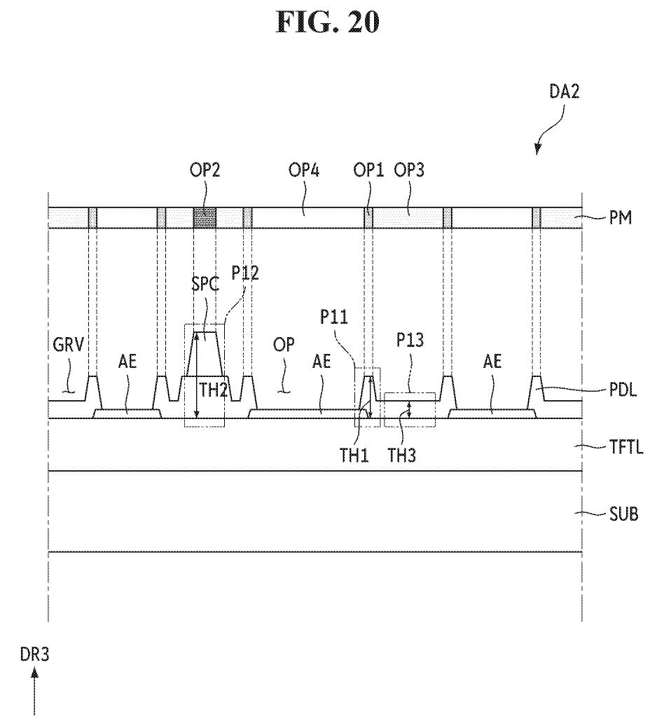

FIGS. 18-20 are cross-sectional views showing processing steps of forming a pixel-defining layer in a display device according to one or more embodiments of the present disclosure.

Referring to FIGS. 18-20 in conjunction with FIGS. 8 and 9, a pixel-defining layer PDL may be formed using a halftone mask PM.

First, as shown in FIG. 18, a material layer PDL_M for forming a pixel-defining layer may be formed over pixel electrodes AE and a thin-film transistor layer TFTL.

Subsequently, as shown in FIG. 19, a photoresist PR may be formed on the material layer PDL_M. Subsequently, a halftone mask PM may be placed above the photoresist PR.

Subsequently, as shown in FIGS. 19 and 20, the photoresist PR may be developed using the halftone mask PM, and the material layer PDL_M may be etched using the developed photoresist PR, thereby forming a pixel-defining layer PDL.

For a positive photoresist, a part of the photoresist that has been exposed to light dissolves in a developer. For a negative photoresist, a part of the photoresist that has not been exposed to light dissolves in a developer. The material layer PDL_M under the remaining part of the photoresist PR may remain unetched, whereas the material layer PDL_M under the removed part of the photoresist PR may be etched and removed.

The halftone mask PM may include a first transmissive portion OP1, a second transmissive portion OP2, a third transmissive portion OP3 and a fourth transmissive portion OP4 having different transmittances for exposure light. The first transmissive portion OP1 may be a portion for forming the first portion P11 of the pixel-defining layer PDL. The second transmissive portion OP2 may be a portion for forming the second portion P12 of the pixel-defining layer PDL. The third transmissive portion OP3 may be a portion for forming the third portion P13 of the pixel-defining layer PDL. The fourth transmissive portion OP4 may be a portion for forming the opening OP of the pixel-defining layer PDL or the transparent window OP_T. For example, in one or more embodiments, the halftone mask PM may include the fourth transmissive portion OP4 aligned with the openings and/or the transparent window OP_T.

Different amounts of exposure light may be incident on the photoresist PR through the first to fourth transmissive portions OP1, OP2, OP3 and OP4 of the halftone mask PM. For a positive photoresist, a part of the photoresist that has been exposed to more light dissolves more in a developer. For a negative photoresist, a part of the photoresist that has been exposed to less light dissolves more in a developer. Accordingly, for a positive photoresist, the transmittance for exposure light may be higher to lower in an order from the fourth transmissive portion OP4, the third transmissive portion OP3, the first transmissive portion OP1, to the second transmissive portion OP2. For a negative photoresist, the transmittance for exposure light may be higher to lower in an order from the second transmissive portion OP2, the first transmissive portion OP1, the third transmissive portion OP3, to the fourth transmissive portion OP4.

According to one or more embodiments, for a positive photoresist, the transmittance of the fourth transmissive portion OP4 to the exposure light may be approximately 100%, the transmittance of the third transmissive portion OP3 to the exposure light may be approximately 90% to 95%, the transmittance of the first transmissive portion OP1 to the exposure light may be approximately 60% to 70%, and the transmittance of the third transmissive portion OP3 to the exposure light may be 0% to 5%.

According to one or more embodiments, for a negative photoresist, the transmittance of the fourth transmissive portion OP4 to the exposure light may be approximately 0%, the transmittance of the third transmissive portion OP3 to the exposure light may be approximately 5% to 10%, the transmittance of the first transmissive portion OP1 to the exposure light may be approximately 30% to 40%, and the transmittance of the second transmissive portion OP2 to the exposure light may be 90% to 100%.

The display device 10 according to the above-described embodiments may be applied to a variety of electronic devices 1. The electronic device 1 according to one or more embodiments may include the above-described display device 10, and may further include a module or device having additional functions in addition to the display device 10.

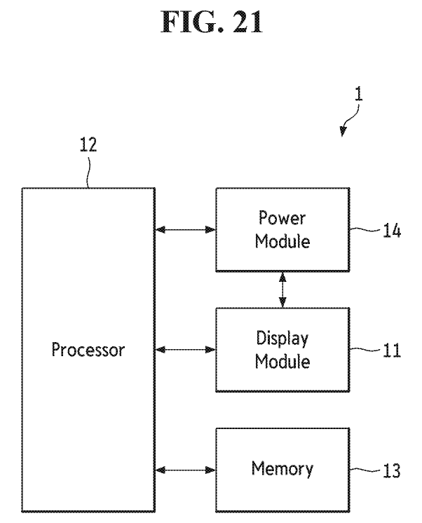

FIG. 21 is a block diagram of an electronic device according to one or more embodiments of the present disclosure.

Referring to FIG. 21, an electronic device 1 according to one or more embodiments of the present disclosure may include a display module 11, a processor 12, a memory 13, and a power module 14.

The processor 12 may include at least one of: a central processing unit (CPU), an application processor (AP), a graphic processing unit (GPU), a communication processor (CP), an image signal processor (ISP), and/or a controller.

The memory 13 may store data information for the operation of the processor 12 or the display module 11. When the processor 12 executes an application stored in the memory 13, an image data signal and/or an input control signal may be transmitted to the display module 11. The display module 11 may process the received signal and output image information through a display screen.

The power module 14 may include a power supply module such as a power adapter and a battery device, and a power conversion module that converts the power supplied by the power supply module to generate power for the operation of the electronic device 1.

At least one of the elements of the electronic device 1 described above may be included in the display device 10 according to one or more embodiments described above. In addition, some of the individual modules functioning as a single module may be included in the display device 10 while some others may be provided separately from the display device 10. For example, the display device 10 may include the display module 11, and the processor 12; the memory 13 and the power module 14 may be provided as other devices inside the electronic device 1 other than the display device 10.

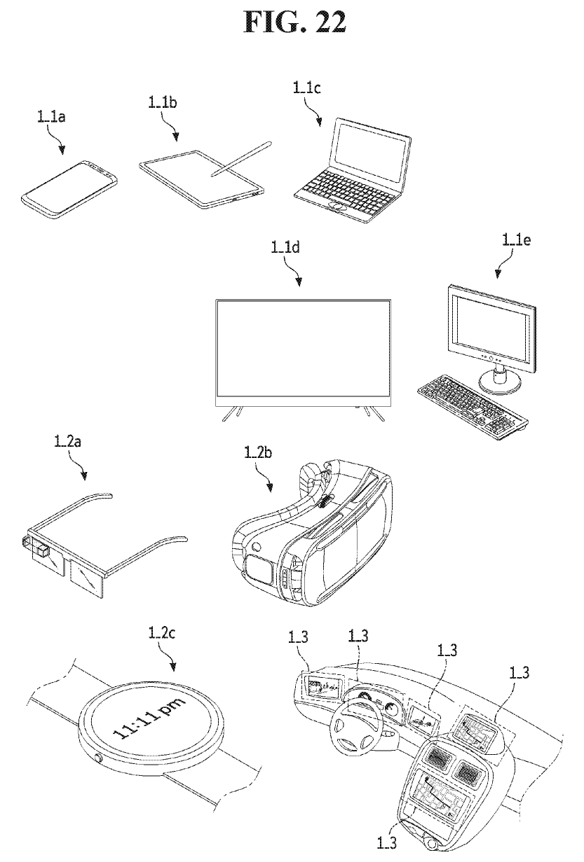

FIG. 22 shows schematic perspective views of electronic devices according to a variety of embodiments of the present disclosure.

Referring to FIG. 22, a variety of electronic devices 1 employing the display devices 10 according to one or more embodiments may include not only image a display electronic device such as a smart phone 1_1a, a tablet PC 1_1b, a laptop computer 1_1c, a TV 1_1d and a desktop monitor 1_1e, but also wearable electronic devices including display modules such as smart glasses 1_2a, a head-mounted display 1_2b and a smart watch 1_2c, and electronic devices for vehicles 1_3 including display modules such as a center information display (CID) placed on the dashboard, the center fascia and the dashboard of a vehicle, and a room mirror display.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” “approximately,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ± 30%, 20%, 10%, 5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, electronic device, device for manufacturing the display device, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a display area having a first display area and a second display area adjacent the first display area;
a substrate;
a thin-film transistor layer on the substrate and comprising at least one conductive pattern;
an emission material layer on the thin-film transistor layer and comprising a pixel-defining layer, the pixel-defining layer comprising a partition wall defining a plurality of openings, and the plurality of openings defining a plurality of emission areas; and
an optical device in the second display area,
wherein the partition wall of the pixel-defining layer comprises a first portion and a second portion, and
wherein a thickness of the first portion is greater than a thickness of the second portion.

2. The display device of claim 1, wherein the second portion is in the second display area.

3. The display device of claim 1, wherein the pixel-defining layer comprises the first portion but not the second portion in the first display area.

4. The display device of claim 1,
wherein the partition wall of the pixel-defining layer define a groove in the second display area, and
wherein the second portion overlaps the groove.

5. The display device of claim 1, wherein the first portion is around the plurality of emission areas in a plan view, and
wherein the second portion is around the first portion in the plan view.

6. The display device of claim 1, wherein the second portion is located in a remaining area of the second display area excluding the plurality of emission areas and the first portion.

7. The display device of claim 1, wherein the thickness of the first portion is in a range from 1 µm to 2 µm, and
wherein the thickness of the second portion is equal to or less than 0.5 µm.

8. The display device of claim 1, wherein the pixel-defining layer further comprises a third portion comprising a part of the partition wall and a spacer on the part of the partition wall, and
wherein a thickness of the third portion is greater than the thickness of the first portion and the thickness of the second portion.

9. The display device of claim 8, wherein the thickness of the third portion is in a range from 2.5 μm to 3.5 μm.

10. The display device of claim 1, wherein the plurality of emission areas comprise a plurality of light-emitting elements,
wherein each of the plurality of light-emitting elements comprises a first electrode, an emissive layer and a second electrode,
wherein the first electrode is located under the pixel-defining layer,
wherein the emissive layer is located in a respective one of the plurality of openings,
wherein the second electrode is located on the pixel-defining layer, and
wherein the second electrode conforms to a shape of an upper surface and side surfaces of the pixel-defining layer.

11. The display device of claim 10, further comprising:
an encapsulation layer on the emission material layers,
wherein the encapsulation layer comprises a first encapsulation layer comprising an inorganic film, a second encapsulation layer on the first encapsulation layer and comprising an organic film, and a third encapsulation layer on the second encapsulation layer and comprising an inorganic film, and
wherein the first encapsulation layer conforms to a shape of an upper surface and side surfaces of the second electrode.

12. The display device of claim 11, wherein the second encapsulation layer provides a flat surface over the first encapsulation layer.

13. The display device of claim 1, wherein the first portion comprises a plurality of first portions,
wherein the second display area further comprises a transparent window around the plurality of emission areas and around the plurality of first portions,
wherein the pixel-defining layer is not arranged in the transparent window, and
wherein the second portion comprises a bridge for connecting adjacent ones of the plurality of first portions.

14. The display device of claim 13, wherein the plurality of emission areas comprises a plurality of light-emitting elements,
wherein each of the plurality of light-emitting elements comprises a first electrode, an emissive layer and a second electrode,
wherein the first electrode is located under the pixel-defining layer,
wherein the emissive layer is located in the plurality of openings,
wherein the second electrode is located on the pixel-defining layer, and
wherein the second electrode is in direct contact with the thin-film transistor layer at the transparent window.

15. The display device of claim 1,
wherein the first portion comprises a plurality of first portions,
wherein the second display area further comprises a transparent window around the plurality of emission areas and around the plurality of first portions,
wherein the pixel-defining layer is not arranged in the transparent window, and
wherein the second portion of the pixel-defining layer overlaps the conductive pattern.

16. The display device of claim 1, wherein the second display area comprises transparent windows in a closed region between the plurality of emission areas.

17. The display device of claim 1, wherein the pixel-defining layer comprises a light-absorbing material.

18. The display device of claim 1, further comprising:
a color filter layer on the emission material layer,
wherein the color filter layer comprises a plurality of color filters overlapping the plurality of emission areas and the plurality of openings.

19. The display device of claim 1, wherein the pixel-defining layer is formed utilizing a halftone mask,
wherein the halftone mask comprises a first transmissive portion configured to overlap the first portion, a second transmissive portion configured to overlap the second portion, and a third transmissive portion configured to overlap the plurality of openings, and
wherein the first to third transmissive portions have different transmittances.

20. An electronic device comprising:
a display device to display an image, the display device having a first display area and a second display area adjacent the first display area;
a processor to provide an image driving signal to the display device; and
a power module to supply power to the display device and the processor,
wherein the display device comprises:
a substrate;
a thin-film transistor layer on the substrate and comprising at least one conductive pattern;
an emission material layer on the thin-film transistor layer and comprising
a pixel-defining layer, the pixel-defining layer comprising a partition wall defining a plurality of openings, and the plurality of openings defining a plurality of emission areas; and
an optical device in the second display area,
wherein the pixel-defining layer comprises a first portion and a second portion, and
wherein a thickness of the first portion is greater than a thickness of the second portion.
